(19) United States
(12) Patent Application Publication
(10) Pub. No.: US 2023/0298945 A1
(43) Pub. Date: Sep. 21, 2023

(54) SEMICONDUCTOR DEVICE

(71) Applicant: SAMSUNG ELECTRONICS CO., LTD., Suwon-si (KR)

(72) Inventors: Junggil YANG, Hwaseong-si (KR); Inhyun SONG, Suwon-si (KR); Jooho JUNG, Suwon-si (KR)

(21) Appl. No.: 17/961,172

(22) Filed: Oct. 6, 2022

(30) Foreign Application Priority Data
Feb. 25, 2022 (KR) 10-2022-0025542

(51) Int. Cl. H01L 21/8238

(52) U.S. Cl. CPC H01L 21/823807; H01L 21/823821; H01L 21/823828; H01L 21/823878

(57) ABSTRACT

A semiconductor device may include first and second channel patterns, which are provided on first and second active patterns, respectively, and include first semiconductor patterns and second semiconductor patterns, respectively, and a gate electrode crossing over the first and second channel patterns in a first direction. The gate electrode may include first and second outer gate electrodes, which are provided on the uppermost ones of the first and second semiconductor patterns, respectively, and each of which includes a first metal pattern, a second metal pattern thinner than the first metal pattern, and a filling metal pattern sequentially stacked. A third metal pattern may be further provided between the first metal pattern and the first semiconductor patterns. The third and second metal patterns may include p- and n-type work function metals, respectively. The first and second metal patterns of the second outer gate electrode may have coplanar topmost surfaces.

### CROSS-REFERENCE TO RELATED APPLICATIONS

This U.S. non-provisional patent application claims priority under 35 U.S.C. §119 to Korean Patent Application No. 10-2022-0025542, filed on Feb. 25, 2022, in the Korean Intellectual Property Office, the entire contents of which are hereby incorporated by reference.

### BACKGROUND

### 1. Field

The present disclosure relates to a semiconductor device, and in particular, to a semiconductor device including a field effect transistor.

### 2. Description of the Related Art

A semiconductor device may include an integrated circuit having metal-oxide-semiconductor field-effect transistors (MOS-FETs). To meet an increasing demand for a semiconductor device with a small pattern size and a reduced design rule, the MOS-FETs are being scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

According to an embodiment, a semiconductor device may include a first active pattern and a second active pattern on a first region and a second region of a substrate, a first channel pattern on the first active pattern, the first channel pattern including first semiconductor patterns, which are stacked to be spaced apart from each other, a second channel pattern on the second active pattern, the second channel pattern including second semiconductor patterns, which are stacked to be spaced apart from each other, and a gate electrode provided on the first and second channel patterns and extended in a first direction. The gate electrode may include a first outer gate electrode and a second outer gate electrode, which are respectively provided on a top surface of the uppermost one of the first semiconductor patterns and a top surface of the uppermost one of the second semiconductor patterns. Each of the first and second outer gate electrodes may include a first metal pattern, a second metal pattern on the first metal pattern, and a filling metal pattern on the second metal pattern. The first outer gate electrode may further include a third metal pattern between the first metal pattern and the first semiconductor patterns. The third metal pattern may include a p-type work function metal, and the second metal pattern may include an n-type work function metal. A thickness of the first metal pattern may be smaller than a thickness of the second metal pattern, and the topmost surface of the first metal pattern of the second outer gate electrode may be coplanar with the topmost surface of the second metal pattern of the second outer gate electrode.

According to an embodiment, a semiconductor device may include a substrate including a first region and a second region, which are adjacent to each other in a first direction, a first active pattern on the first region and a second active pattern on the second region, a first channel pattern on the first active pattern and a second channel pattern on the second active pattern; a gate electrode provided to cross the first and second channel pattern and extended in the first direction, the gate electrode including a first gate portion on the first region and a second gate portion on the second region, and a gate insulating layer between the gate electrode and the first and second channel patterns. The first channel pattern includes first semiconductor patterns, which are stacked to be spaced apart from each other. The second channel pattern includes second semiconductor patterns, which are stacked to be spaced apart from each other, Each of the first gate portion and the second gate portion may include a first metal pattern, a second metal pattern on the first metal pattern, and a filling metal pattern on the second metal pattern. The first gate portion may further include a third metal pattern between the first metal pattern and the first channel pattern. The third metal pattern may include a p-type work function metal, and the second metal pattern may include an n-type work function metal. A thickness of the first metal pattern may be smaller than a thickness of each of the second and third metal patterns. The topmost surface of the first metal pattern may be flat, and the second metal pattern may be spaced apart from an inner side surface of the gate insulating layer by the first metal pattern.

According to an embodiment, a semiconductor device may include a first active pattern and a second active pattern on a first region and a second region of a substrate, the first and second regions being PMOSFET and NMOSFET regions, respectively, a device isolation layer filling a trench between the first and second active patterns, a first channel pattern on the first active pattern and a second channel pattern on the second active pattern, the first channel pattern including first semiconductor patterns, which are stacked to be spaced apart from each other, the second channel pattern including second semiconductor patterns, which are stacked to be spaced apart from each other, a gate electrode provided to cross the first and second channel patterns and extended in a first direction, the gate electrode including first inner gate electrodes between the first semiconductor patterns, second inner gate electrodes between the second semiconductor patterns, a first outer gate electrode on a top surface of the uppermost one of the first semiconductor patterns, and a second outer gate electrode on a top surface of the uppermost one of the second semiconductor patterns, a gate insulating layer interposed between the gate electrode and the first and second channel patterns, the gate insulating layer including an interface layer enclosing the first and second semiconductor patterns and a high-k dielectric layer on the interface layer, a gate capping pattern on a top surface of the gate electrode, a first interlayer insulating layer on the gate capping pattern, a gate contact provided to penetrate the first interlayer insulating layer and coupled to the gate electrode, a second interlayer insulating layer on the first interlayer insulating layer, a first metal layer provided in the second interlayer insulating layer, a third interlayer insulating layer on the second interlayer insulating layer, and a second metal layer provided in the third interlayer insulating layer. Each of the first and second outer gate electrodes may include a first metal pattern, a second metal pattern on the first metal pattern, and a filling metal pattern on the second metal pattern. The first outer gate electrode may further include a third metal pattern between the first metal pattern and the first semiconductor patterns. The third metal pattern may include a p-type work function metal, and the second metal pattern may include an n-type work function metal. A thickness of the first metal pattern may be smaller than a thickness of each of the second and third metal patterns, and the topmost surface of the first metal pattern of the second outer gate electrode may be coplanar with the topmost surface of the second metal pattern of the second outer gate electrode.

### BRIEF DESCRIPTION OF THE DRAWINGS

Features will become apparent to those of skill in the art by describing in detail exemplary embodiments with reference to the attached drawings, in which:

FIG. 1 is a plan view of a semiconductor device according to an embodiment.

FIGS. 2A to 2D are sectional views along lines A-A′, B-B′, C-C′, and D-D′, respectively, of FIG. 1.

FIG. 3A is an enlarged sectional view of portion ‘M’ of FIG. 2A.

FIG. 3B is an enlarged sectional view of portion ‘N’ of FIG. 2B.

FIG. 3C is an enlarged sectional view of portion ‘O’ of FIG. 2D.

FIG. 3D is an enlarged sectional view of portion ‘P’ of FIG. 2D.

FIGS. 4A to 12D are sectional views of stages in a method of fabricating a semiconductor device according to an embodiment.

FIGS. 13A to 16B are sectional views of stages in a method of fabricating a semiconductor device according to a comparative example.

FIGS. 17A to 19B are sectional views of stages in a method of fabricating a semiconductor device according to a comparative example.

FIGS. 20A to 20D are sectional views along lines A-A′, B-B′, C-C′, and D-D′ of FIG. 1, respectively.

### DETAILED DESCRIPTION

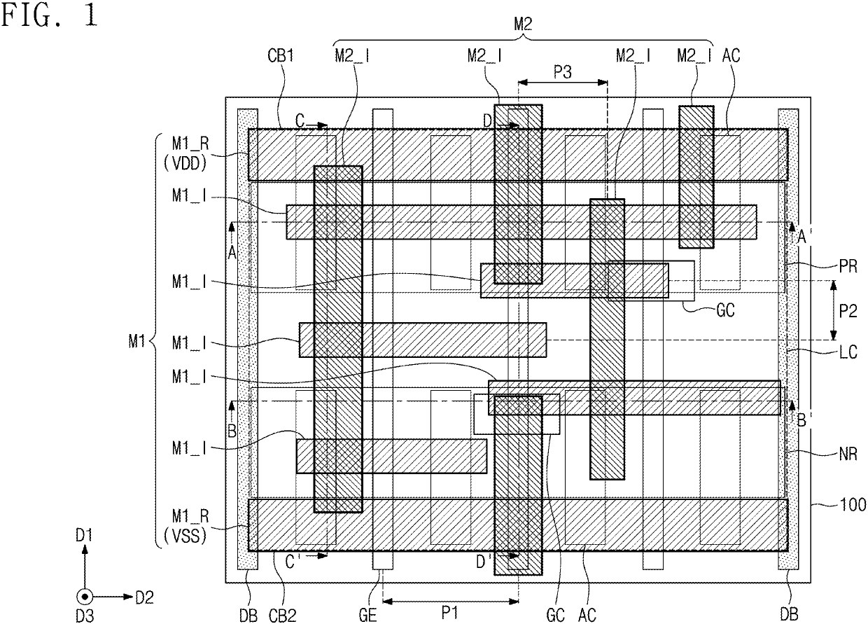

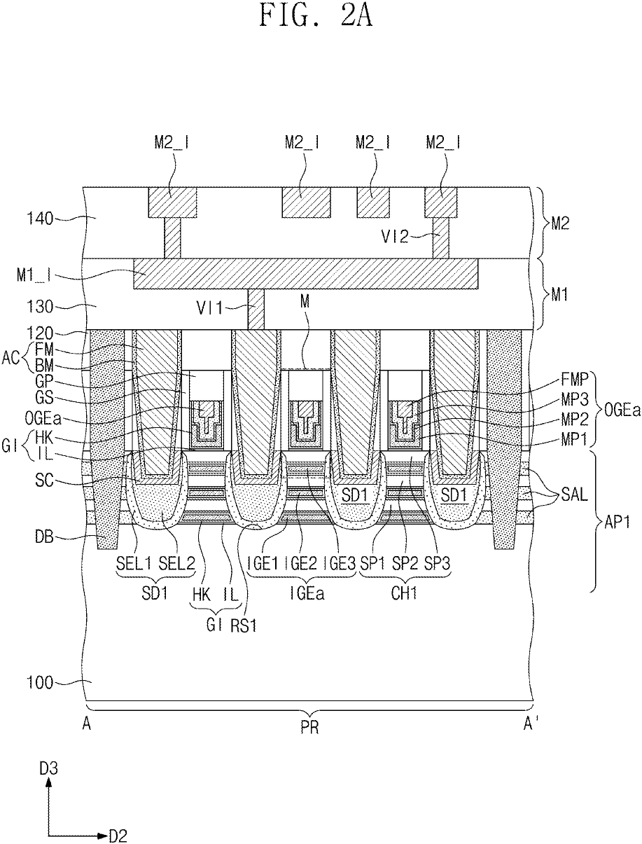

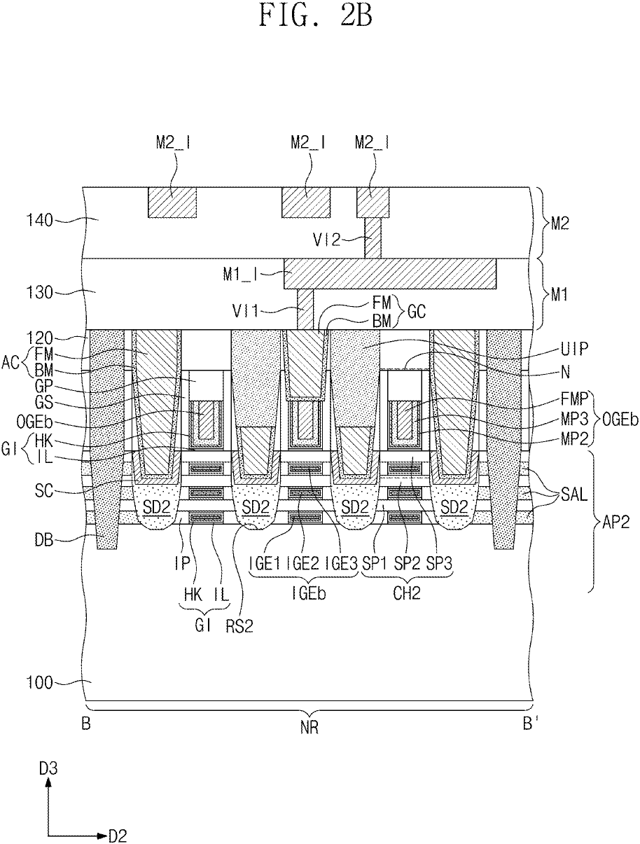

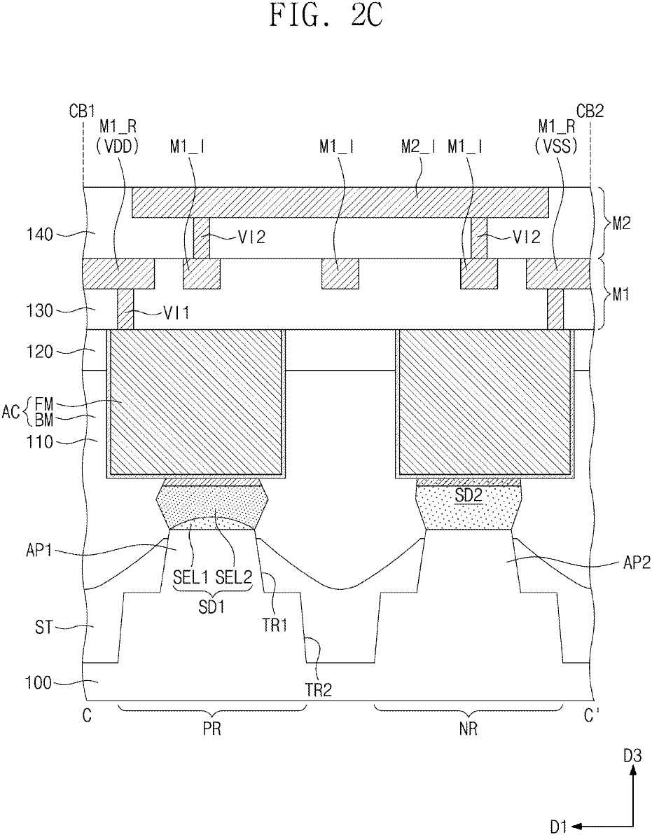

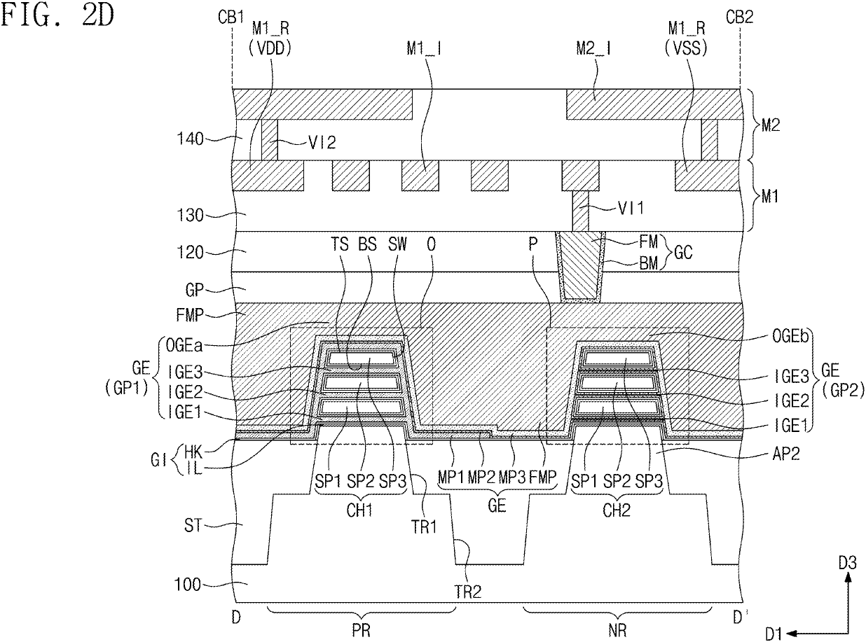

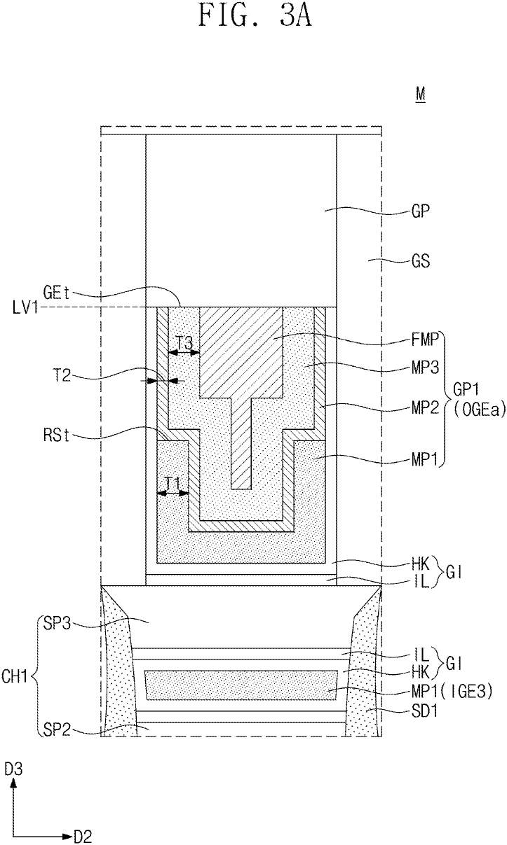

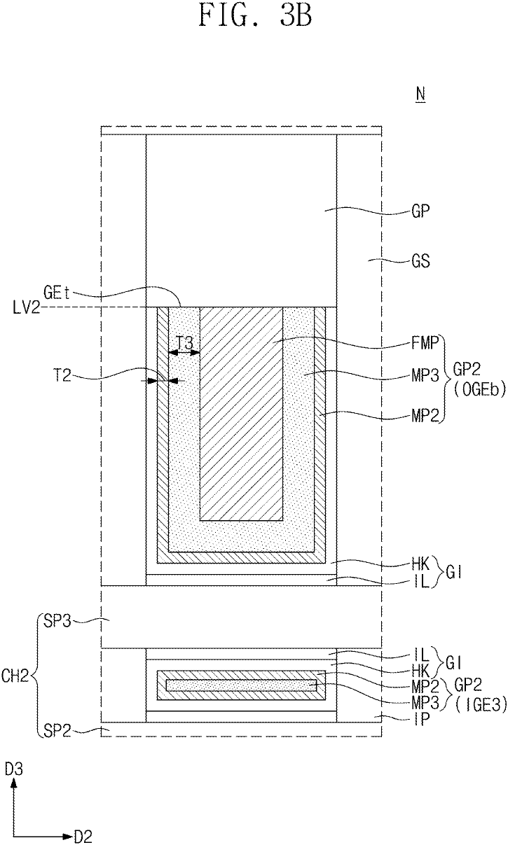

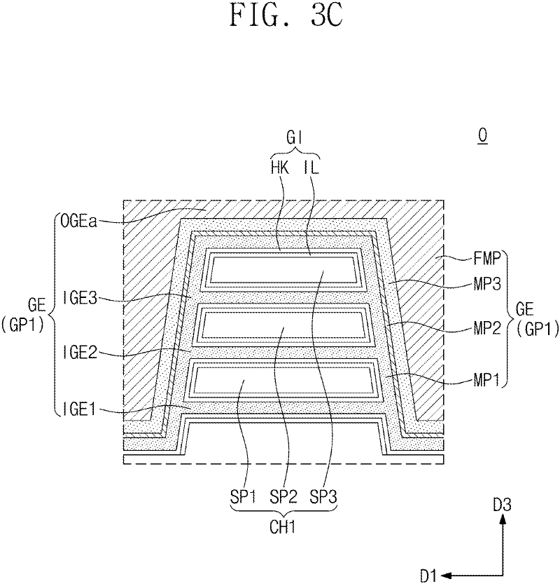

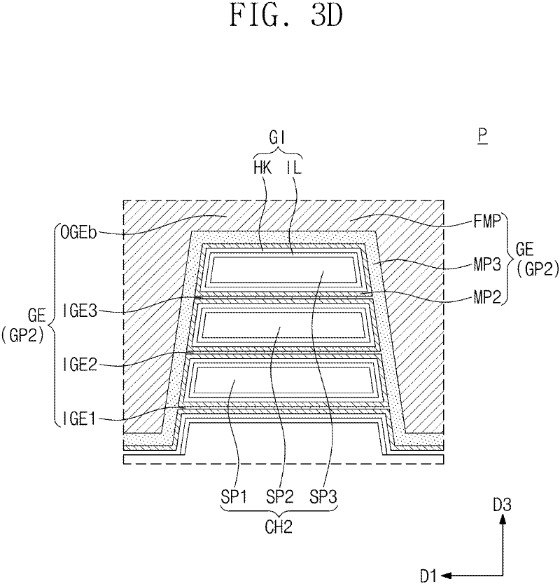

FIG. 1 is a plan view of a semiconductor device according to an embodiment. FIGS. 2A to 2D are cross-sectional views along lines A-A′, B-B′, C-C′, and D-D′, respectively, of FIG. 1. FIG. 3A is an enlarged cross-sectional view of portion ‘M’ of FIG. 2A. FIG. 3B is an enlarged cross-sectional view of portion ‘N’ of FIG. 2B. FIG. 3C is an enlarged cross-sectional view of portion ‘O’ of FIG. 2D. FIG. 3D is an enlarged cross-sectional view of portion ‘P’ of FIG. 2D.

Referring to FIGS. 1 and 2A to 2D, a logic cell LC may be provided on a substrate 100. Logic transistors constituting a logic circuit may be disposed on the logic cell LC. The substrate 100 may be a semiconductor substrate that is formed of or includes, e.g., silicon, germanium, silicon germanium, a compound semiconductor material, or the like. In an embodiment, the substrate 100 may be a silicon wafer. The logic cell LC may include a first region PR and a second region NR. The first region PR may be one of PMOSFET and NMOSFET regions. The second region NR may be the other of the PMOSFET and NMOSFET regions. In an embodiment, the first region PR may be the PMOSFET region, and the second region NR may be the NMOSFET region.

The first and second regions PR and NR may be defined by a second trench TR2, which is formed in an upper portion of the substrate 100. In other words, the second trench TR2 may be located between the first and second regions PR and NR. The first and second regions PR and NR may be spaced apart from each other in a first direction D1 with the second trench TR2 interposed therebetween.

A first active pattern AP1 and a second active pattern AP2 may be defined by a first trench TR1, which is formed in an upper portion of the substrate 100. The first and second active patterns AP1 and AP2 may be provided on the first and second regions PR and NR, respectively. The first trench TR1 may be shallower than the second trench TR2, e.g., a distance from a bottom of the first trench TR1 to a bottom of the substrate 100 may be larger than a distance from a bottom of the second trench TR2 to the bottom of the substrate 100. The first and second active patterns AP1 and AP2 may be extended in a second direction D2. The first and second active patterns AP1 and AP2 may be vertically-protruding portions of the substrate 100, e.g., along a third direction D3.

A device isolation layer ST may be provided to fill the first and second trenches TR1 and TR2. The device isolation layer ST may include, e.g., a silicon oxide layer. The device isolation layer ST may not cover first and second channel patterns CH1 and CH2 to be described below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., the third direction D3). The third semiconductor pattern SP3 may be the uppermost one of the first to third semiconductor patterns SP1, SP2, and SP3.

Each of the first to third semiconductor patterns SP1, SP2, and SP3 may be formed of or include silicon (Si), germanium (Ge), or silicon germanium (SiGe). In an embodiment, each of the first to third semiconductor patterns SP1, SP2, and SP3 may be formed of or include crystalline silicon.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in the upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between each pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. For example, each of the first and second source/drain patterns SD1 and SD2 may have a top surface that is located at substantially the same level as a top surface of the third semiconductor pattern SP3. In another example, the top surface of each of the first and second source/drain patterns SD1 and SD2 may be higher than the top surface of the third semiconductor pattern SP3.

The first source/drain patterns SD1 may include a semiconductor material (e.g., SiGe) having a lattice constant greater than that of the substrate 100. In this case, the pair of the first source/drain patterns SD1 may exert a compressive stress on the first channel patterns CH1 therebetween. The second source/drain patterns SD2 may be formed of or include the same semiconductor material (e.g., Si) as the substrate 100.

Each of the first source/drain patterns SD1 may include a first semiconductor layer SEL1 and a second semiconductor layer SEL2, which are sequentially stacked. A sectional shape of the first source/drain pattern SD1 taken parallel to the second direction D2 will be described with reference to FIG. 2A.

Referring to FIG. 2A, the first semiconductor layer SEL1 may cover an inner surface of the first recess RS1. The first semiconductor layer SEL1 may have a decreasing thickness in an upward direction. For example, the thickness of the first semiconductor layer SEL1, which is measured in the third direction D3 at the bottom level of the first recess RS1, may be larger than the thickness of the first semiconductor layer SEL1, which is measured in the second direction D2 at the top level of the first recess RS1. The first semiconductor layer SEL1 may have a ‘U’-shaped cross-section, due to a cross-sectional profile of the first recess RS1.

The second semiconductor layer SEL2 may fill a remaining space of the first recess RS1 excluding the first semiconductor layer SEL1. A volume of the second semiconductor layer SEL2 may be larger than a volume of the first semiconductor layer SEL1. In other words, a ratio of a total volume of the second semiconductor layer SEL2 to a total volume of the first source/drain pattern SD1 may be greater than a ratio of a total volume of the first semiconductor layer SEL1 to the total volume of the first source/drain pattern SD1.

Each of the first and second semiconductor layers SEL1 and SEL2 may be formed of or include, e.g., silicon germanium (SiGe). For example, the first semiconductor layer SEL1 may be provided to have a relatively low germanium concentration. In another example, the first semiconductor layer SEL1 may be provided to contain only silicon (Si) and not germanium (Ge). The germanium concentration of the first semiconductor layer SEL1 may range from about 0 at% to about 10 at%.

The second semiconductor layer SEL2 may be provided to have a relatively high germanium concentration. For example, the germanium concentration of the second semiconductor layer SEL2 may range from about 30 at% to about 70 at%. The germanium concentration of the second semiconductor layer SEL2 may increase in the third direction D3. For example, the germanium concentration of the second semiconductor layer SEL2 may be about 40 at% near the first semiconductor layer SEL1, e.g., at the bottom of the U-shape at an end closer to the substrate 100, but may be about 60 at% at its top level, e.g., at the top of the U-shape at an end farther from the substrate 100.

The first and second semiconductor layers SEL1 and SEL2 may include impurities (e.g., boron), allowing the first source/drain pattern SD1 to have the p-type conductivity. In an embodiment, a concentration of impurities in the second semiconductor layer SEL2 (in at%) may be higher than that in the first semiconductor layer SEL1.

The first semiconductor layer SEL1 may prevent a stacking fault from occurring between the substrate 100 and the second semiconductor layer SEL2 and between the first to third semiconductor patterns SP1, SP2, and SP3 and the second semiconductor layer SEL2. The stacking fault may lead to an increase of a channel resistance. In an embodiment, the first semiconductor layer SEL1 may be provided to have a relatively large thickness near the bottom of the first recess RS1, and in this case, it may be possible to prevent the stacking fault, e.g., at the bottom of the first recess RS1.

The first semiconductor layer SEL1 may be used to protect the second semiconductor layer SEL2, in a process of replacing sacrificial layers SAL with first to third inner gate electrodes IGE1, IGE2, and IGE3 of a gate electrode GE, which will be described below. For example, the first semiconductor layer SEL1 may prevent the second semiconductor layer SEL2 from being undesirably etched by an etching material, which is used to remove the sacrificial layers SAL.

The gate electrodes GE may be provided to cross the first and second channel patterns CH1 and CH2, and to extend in the first direction D1. The gate electrodes GE may be arranged with a first pitch P1 in the second direction D2. Each of the gate electrodes GE may be vertically overlapped with the first and second channel patterns CH1 and CH2.

The gate electrode GE may include a first gate portion GP1 on the first region PR and a second gate portion GP2 on the second region NR. The gate electrode GE may include a first metal pattern MP1, a second metal pattern MP2, a third metal pattern MP3, and a filling metal pattern FMP. The first and second gate portions GP1 and GP2, the first to third metal patterns MP1, MP2, and MP3, and the filling metal pattern FMP may contain metal and will be described in more detail with reference to FIGS. 3A-3D.

Referring back to FIG. 2D, the gate electrode GE may be provided on a top surface, a bottom surface, and opposite side surfaces of each of the first to third semiconductor patterns SP1, SP2, and SP3. In other words, the transistor according to the present embodiment may be a three-dimensional field-effect transistor (e.g., multi-bridge channel field-effect transistor (MBCFET)), in which the gate electrode GE is provided to three-dimensionally surround the channel pattern.

Each of the first and second gate portions GP1 and GP2 may include an inner gate electrode IGEa or IGEb and an outer gate electrode OGE. The first gate portion GP1 may include an inner gate electrode IGEa and a first outer gate electrode OGEa on the first region PR. The second gate portion GP2 may include an inner gate electrode IGEb and a second outer gate electrode OGEb on the second region NR.

The inner gate electrode IGEa on the first region PR may be vertically overlapped with the first channel pattern CH1. The inner gate electrode IGEa may include a first inner gate electrode IGE1 between the first active pattern AP1 and the first semiconductor pattern SP1, a second inner gate electrode IGE2 between the first semiconductor pattern SP1 and the second semiconductor pattern SP2, and a third inner gate electrode IGE3 between the second semiconductor pattern SP2 and the third semiconductor pattern SP3.

Referring back to FIG. 2A, the first to third inner gate electrodes IGE1, IGE2, and IGE3 on the second region NR may have different widths from each other, e.g., in the second direction D2. For example, the largest width of the third inner gate electrode IGE3 in the second direction D2 may be larger than the largest width of the second inner gate electrode IGE2 in the second direction D2. The largest width of the first inner gate electrode IGE1 in the second direction D2 may be larger than the largest width of the third inner gate electrode IGE3 in the second direction D2.

The inner gate electrode IGEb on the second region NR may be vertically overlapped with the second channel pattern CH2. The inner gate electrode IGEb may include the first inner gate electrode IGE1 between the second active pattern AP2 and the first semiconductor pattern SP1, the second inner gate electrode IGE2 between the first semiconductor pattern SP1 and the second semiconductor pattern SP2, and the third inner gate electrode IGE3 between the second semiconductor pattern SP2 and the third semiconductor pattern SP3.

The first outer gate electrode OGEa on the first region PR may be provided on the top surface of the third semiconductor pattern SP3. The first outer gate electrode OGEa may be provided on side surfaces of the first to third inner gate electrodes IGE1, IGE2, and IGE3 on the first region PR. The first outer gate electrode OGEa may not be provided in a space between adjacent ones of the first to third semiconductor patterns SP1, SP2, and SP3.

The second outer gate electrode OGEb on the second region NR may be provided on the top surface of the third semiconductor pattern SP3. The second outer gate electrode OGEb may be provided on side surfaces of the first to third inner gate electrodes IGE1, IGE2, and IGE3 on the second region NR. The second outer gate electrode OGEb may not be provided in a space between adjacent ones of the first to third semiconductor patterns SP1, SP2, and SP3.

Referring back to FIGS. 1 and 2A to 2D, a pair of gate spacers GS may be respectively disposed on opposite side surfaces of each of the first and second outer gate electrodes OGEa and OGEb. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. The gate spacers GS may be formed of or include at least one of, e.g., SiCN, SiCON, or SiN. In an embodiment, the gate spacers GS may have a multi-layered structure, which may include at least two different materials of SiCN, SiCON, and SiN.

A gate capping pattern GP may be provided on the gate electrode GE. The gate capping pattern GP may be extended along the gate electrode GE or in the first direction D1. The gate capping pattern GP may be formed of or include a material having an etch selectivity with respect to the first and second interlayer insulating layers 110 and 120, which will be described below. In detail, the gate capping pattern GP may be formed of or include at least one of, e.g., SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover top, bottom, and opposite side surfaces of each of the first to third semiconductor patterns SP1, SP2, and SP3. The gate insulating layer GI may cover a top surface of the device isolation layer ST below the gate electrode GE (e.g., see FIG. 2D).

The gate insulating layer GI may include an interface layer IL and a high-k dielectric layer HK on the interface layer IL. The interface layer IL may be provided to enclose each of the first to third semiconductor patterns SP1, SP2, and SP3. The interface layer IL may include, e.g., a silicon oxide layer or a silicon oxynitride layer.

The high-k dielectric layer HK may be formed of or include a high-k dielectric material whose dielectric constant is higher than that of silicon oxide. For example, the high-k dielectric materials may be formed of or include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate. The high-k dielectric layer HK may be extended along a bottom surface of the gate electrode GE or in the first direction D1.

In another embodiment, the semiconductor device may include a negative capacitance (NC) FET using a negative capacitor. For example, the gate insulating layer GI may include a ferroelectric layer exhibiting a ferroelectric material property and a paraelectric layer exhibiting a paraelectric material property.

The ferroelectric layer may have a negative capacitance, and the paraelectric layer may have a positive capacitance. In the case where two or more capacitors are connected in series and each capacitor has a positive capacitance, a total capacitance may be less than a capacitance of each of the capacitors. In contrast, in the case where at least one of serially-connected capacitors has a negative capacitance, a total capacitance of the serially-connected capacitors may have a positive value and may be greater than an absolute value of each capacitance.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS) less than 60 mV/decade, at room temperature.

The ferroelectric layer may have a ferroelectric material property. The ferroelectric layer may be formed of or include at least one of, e.g., hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. For example, the dopants may contain at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, e.g., gadolinium (Gd), silicon (Si), zirconium (Zr), aluminum (Al), and/or yttrium (Y).

In the case where the dopants are aluminum (Al), a content of aluminum in the ferroelectric layer may range from 3 to 8 at% (atomic percentage). Here, the content of the aluminum as the dopants may be a ratio of the number of aluminum atoms to the number of hafnium and aluminum atoms.

In the case where the dopants are silicon (Si), a content of silicon in the ferroelectric layer may range from 2 at% to 10 at%. In the case where the dopants are yttrium (Y), a content of yttrium in the ferroelectric layer may range from 2 at% to 10 at%. In the case where the dopants are gadolinium (Gd), a content of gadolinium in the ferroelectric layer may range from 1 at% to 7 at%. In the case where the dopants are zirconium (Zr), a content of zirconium in the ferroelectric layer may range from 50 at% to 80 at%.

The paraelectric layer may have a paraelectric material property. The paraelectric layer may be formed of or include at least one of, e.g., silicon oxide and/or high-k metal oxides. The metal oxides, which can be used as the paraelectric layer, may include at least one of, e.g., hafnium oxide, zirconium oxide, and/or aluminum oxide.

The ferroelectric layer and the paraelectric layer may be formed of or include the same material. The ferroelectric layer may have the ferroelectric material property, but the paraelectric layer may not have the ferroelectric material property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric material property, only when it is in a specific range of thickness. For example, the ferroelectric layer may have a thickness ranging from 0.5 nm to 10 nm. Since a critical thickness associated with the occurrence of the ferroelectric material property varies depending on the kind of the ferroelectric material, the thickness of the ferroelectric layer may be changed depending on the kind of the ferroelectric material.

For example, the gate insulating layer GI may include a single ferroelectric layer. In another example, the gate insulating layer GI may include ferroelectric layers spaced apart from each other. The gate insulating layer GI may have a multi-layered structure, in which ferroelectric layers and paraelectric layers are alternately stacked.

Referring back to FIG. 2B, inner spacers IP may be provided on the second region NR. The inner spacers IP may be respectively interposed between the first to third inner gate electrodes IGE1, IGE2, and IGE3 of the gate electrode GE and the second source/drain pattern SD2. The inner spacers IP may be in direct contact with the second source/drain pattern SD2. Each of the first to third inner gate electrodes IGE1, IGE2, and IGE3 of the gate electrode GE may be spaced apart from the second source/drain pattern SD2 by the inner spacer IP.

The first interlayer insulating layer 110 may be provided on the substrate 100. The first interlayer insulating layer 110 may cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be disposed on the first interlayer insulating layer 110 to cover the gate capping pattern GP. In an embodiment, at least one of the first and second interlayer insulating layers 110 and 120 may include a silicon oxide layer.

A pair of division structures DB, which are opposite to each other in the second direction D2, may be provided at both sides of the logic cell LC. The division structure DB may be extended in the first direction D1 to be parallel to the gate electrodes GE. A pitch between the division structure DB and the gate electrode GE adjacent to each other may be equal to the first pitch P1.

The division structure DB may be provided to penetrate the first and second interlayer insulating layers 110 and 120 and may be extended into the first and second active patterns AP1 and AP2. The division structure DB may penetrate the first and second channel patterns CH1 and CH2. The division structure DB may separate the first and second regions PR and NR of the logic cell LC from first and second regions of other logic cells adjacent thereto.

Active contacts AC may penetrate the first and second interlayer insulating layers 110 and 120 and may be electrically connected to the first and second source/drain patterns SD1 and SD2, respectively. A pair of the active contacts AC may be respectively at both sides of the gate electrode GE. When viewed in a plan view, the active contact AC may be a bar-shaped pattern extending in the first direction D1.

The active contact AC may be a self-aligned contact. For example, the active contact AC may be formed by a self-alignment process using the gate capping pattern GP and the gate spacer GS. In an embodiment, the active contact AC may cover at least a portion of the side surface of the gate spacer GS. Although not shown, the active contact AC may cover a portion of the top surface of the gate capping pattern GP.

Silicide patterns SC may be respectively interposed between the active contact AC and the first source/drain pattern SD1, and between the active contact AC and the second source/drain pattern SD2. The active contact AC may be electrically connected to the source/drain pattern SD1 or SD2 through the silicide pattern SC. The silicide pattern SC may be formed of or include at least one of metal silicide materials (e.g., titanium silicide, tantalum silicide, tungsten silicide, nickel silicide, and cobalt silicide).

A gate contact GC may be provided to penetrate the second interlayer insulating layer 120 and the gate capping pattern GP, and may be electrically connected to the gate electrode GE. Referring to FIG. 2B, an upper region of each of the active contacts AC adjacent to the gate contact GC may be filled with an upper insulating pattern UIP. Accordingly, it may be possible to prevent a process failure (e.g., a short circuit), which may occur when the gate contact GC is in contact with the active contact AC adjacent thereto.

Each of the active and gate contacts AC and GC may include a conductive pattern FM and a barrier pattern BM enclosing the conductive pattern FM. For example, the conductive pattern FM may be formed of or include at least one of metallic materials (e.g., aluminum, copper, tungsten, molybdenum, or cobalt). The barrier pattern BM may be provided to cover side and bottom surfaces of the conductive pattern FM. In an embodiment, the barrier pattern BM may include a metal layer and a metal nitride layer. The metal layer may be formed of or include at least one of, e.g., titanium, tantalum, tungsten, nickel, cobalt, or platinum. The metal nitride layer may be formed of or include at least one of, e.g., titanium nitride (TiN), tantalum nitride (TaN), tungsten nitride (WN), nickel nitride (NiN), cobalt nitride (CoN), or platinum nitride (PtN).

A first metal layer M1 may be provided in a third interlayer insulating layer 130. The first metal layer M1 may include first lower interconnection lines M1_R, second lower interconnection lines M1_I, and lower vias VI1. The lower vias VI1 may be provided below the first and second lower interconnection lines M1_R and M1_I.

Each of the first lower interconnection lines M1_R may be extended in the second direction D2 to cross the logic cell LC. Each of the first lower interconnection lines M1_R may be a power line. For example, a drain voltage VDD or a source voltage VSS may be applied to the first lower interconnection line M1_R.

Referring to FIG. 1, a first cell boundary CB1 extending in the second direction D2 may be defined in a region of the logic cell LC. A second cell boundary CB2 extending in the second direction D2 may be defined in a region of the logic cell LC opposite to the first cell boundary CB1. The first lower interconnection line M1_R, to which the drain voltage VDD (i.e., a power voltage) is applied, may be disposed on the first cell boundary CB1. The first lower interconnection line M1_R, to which the drain voltage VDD is applied, may be extended along the first cell boundary CB1 and in the second direction D2. The first lower interconnection line M1_R, to which the source voltage VSS (i.e., a ground voltage) is applied, may be disposed on the second cell boundary CB2. The first lower interconnection line M1_R, to which the source voltage VSS is applied, may be extended along the second cell boundary CB2 and in the second direction D2.

The second lower interconnection lines M1_I may be disposed between the first lower interconnection lines M1_R, to which the drain voltage VDD and the source voltage VSS are respectively applied, and may be arranged in the first direction D1. Each of the second lower interconnection lines M1_I may be a line- or bar-shaped pattern extending in the second direction D2. The second lower interconnection lines M1_I may be arranged with a second pitch P2 in the first direction D1. The second pitch P2 may be smaller than the first pitch P1.

The lower vias VI1 may be provided below the first and second lower interconnection lines M1_R and M1_I of the first metal layer M1. The lower vias VI1 may be respectively interposed between the active contacts AC and the first and second lower interconnection lines M1_R and M1_I. The lower vias VI1 may be respectively interposed between the gate contacts GC and the second lower interconnection lines M1_I.

The lower interconnection line M1_R or M1_I of the first metal layer M1 and the lower via VI1 thereunder may be formed by separate processes. For example, each of the lower interconnection line M1_R or M1_I and the lower via VI1 may be formed by a single damascene process. The semiconductor device according to the present embodiment may be fabricated using a sub-20 nm process.

A second metal layer M2 may be provided in a fourth interlayer insulating layer 140. The second metal layer M2 may include upper interconnection lines M2_I. Each of the upper interconnection lines M2_I may be a line- or bar-shaped pattern extending in the first direction D1. In other words, the upper interconnection lines M2_I may be extended in the first direction D1 to be parallel to each other. When viewed in a plan view, the upper interconnection lines M2_I may be parallel to the gate electrodes GE. The upper interconnection lines M2_I may be arranged with a third pitch P3 in the second direction D2. The third pitch P3 may be smaller than the first pitch P1. The third pitch P3 may be larger than the second pitch P2.

The second metal layer M2 may further include upper vias VI2. The upper vias VI2 may be provided below the upper interconnection lines M2_I. The upper vias VI2 may be respectively interposed between the lower interconnection lines M1_R and M1_I and the upper interconnection lines M2_I.

The upper interconnection line M2_I of the second metal layer M2 and the upper via VI2 thereunder may be formed by the same process and may form a single pattern. For example, the upper interconnection line M2_I and the upper via VI2 of the second metal layer M2 may be formed together by a dual damascene process.

The lower interconnection lines M1_R and M1_I of the first metal layer M1 and the upper interconnection lines M2_I of the second metal layer M2 may be formed of or include the same material or different conductive materials. For example, the lower interconnection lines M1_R and M1_I and the upper interconnection lines M2_I may be formed of or include at least one of metallic materials (e.g., aluminum, copper, tungsten, ruthenium, molybdenum, or cobalt).

For example, additional metal layers (e.g., M3, M4, M5, and so forth) may be further stacked on the fourth interlayer insulating layer 140. Each of the stacked metal layers may include routing lines.

FIG. 3A is an enlarged sectional view of portion ‘M’ of FIG. 2A. FIG. 3B is an enlarged sectional view of portion ‘N’ of FIG. 2B. FIG. 3C is an enlarged sectional view of portion ‘O’ of FIG. 2D. FIG. 3D is an enlarged sectional view of portion ‘P’ of FIG. 2D. The gate electrode GE according to an embodiment will be described in more detail with reference to FIGS. 3A to 3D.

Referring to FIGS. 3A and 3B, the first outer gate electrode OGEa may include the first metal pattern MP1, the second metal pattern MP2, the third metal pattern MP3, and the filling metal pattern FMP, which are sequentially stacked. The first metal pattern MP1 may be provided on the gate insulating layer GI. The first metal pattern MP1 may be formed of or include a p-type work function metal having a relatively high work function. For example, the first metal pattern MP1 may be formed of or include at least one of titanium nitride (TiN), tantalum nitride (TaN), titanium oxynitride (TiON), titanium silicon nitride (TiSiN), titanium aluminum nitride (TiAlN), tungsten carbon nitride (WCN), or molybdenum nitride (MoN). In an embodiment, the first metal pattern MP1 may be formed of or include titanium aluminum nitride (TiAlN). The first metal pattern MP1 may be conformally formed on the high-k dielectric layer HK.

The first metal pattern MP1 may be chamfered such that the topmost surface thereof is lower than the topmost surface GEt of the first outer gate electrode OGEa. The topmost surface GEt of the first outer gate electrode OGEa may be the topmost surface GEt of the gate electrode GE. For example, the first metal pattern MP1 may have a recessed, e.g., lowered, topmost surface RSt. The recessed topmost surface RSt may be lower than the topmost surface GEt of the first outer gate electrode OGEa.

The second metal pattern MP2 may be provided on the first metal pattern MP1 of the first outer gate electrode OGEa. The second metal pattern MP2 may be conformally formed on the first metal pattern MP1. In an embodiment, the second metal pattern MP2 may be formed of or include titanium nitride (TiN). The second metal pattern MP2 may cover the recessed topmost surface RSt of the first metal pattern MP1. The second metal pattern MP2 may be extended to the topmost level of the first outer gate electrode OGEa. The topmost surface of the second metal pattern MP2 may be located at a level higher than the topmost surface of the first metal pattern MP1.

The second outer gate electrode OGEb may include the second metal pattern MP2, the third metal pattern MP3, and the filling metal pattern FMP, which are sequentially stacked. The second metal pattern MP2 of the second outer gate electrode OGEb may be conformally formed along an inner side surface of the high-k dielectric layer HK. The second metal pattern MP2 may be extended to the topmost level of the second outer gate electrode OGEb.

The third metal pattern MP3 may be provided on the second metal pattern MP2. The third metal pattern MP3 may be conformally formed on the second metal pattern MP2. The third metal pattern MP3 may be formed of or include an n-type work function metal. The third metal pattern MP3 may be formed of or include at least one of metal carbides. The third metal pattern MP3 may be formed of or include at least one of metal carbides that are doped with silicon and/or aluminum and contain silicon and/or aluminum. For example, the third metal pattern MP3 may be formed of or include at least one of aluminum-doped titanium carbide (TiAlC), aluminum-doped tantalum carbide (TaAlC), aluminum-doped vanadium carbide (VAlC), silicon-doped titanium carbide (TiSiC), or silicon-doped tantalum carbide (TaSiC). In another example, the third metal pattern MP3 may be formed of or include titanium carbide (TiAlSiC), which is doped with aluminum and silicon, or tantalum carbide (TaAlSiC), which is doped with aluminum and silicon. In yet another example, the third metal pattern MP3 may be formed of or include aluminum-doped titanium (TiAl). In still another example, the third metal pattern MP3 may be formed of or include a metal nitride (e.g., aluminum-doped titanium nitride (TiAlN)) that is doped with silicon and/or aluminum. In detail, the third metal pattern MP3 may be formed of or include aluminum-doped titanium carbide (TiAlC).

The filling metal pattern FMP may be provided on the third metal pattern MP3. The filling metal pattern FMP may fill a space between adjacent ones of the gate spacers GS. For example, the filling metal pattern FMP may be formed of or include titanium nitride (TiN). In another example, the filling metal pattern FMP may be formed of or include at least one of low resistance metals (e.g., aluminum (Al), tungsten (W), titanium (Ti), and tantalum (Ta)).

In the first outer gate electrode OGEa, the topmost surface of the second metal pattern MP2 may be coplanar with the topmost surface of the high-k dielectric layer HK, the topmost surface of the third metal pattern MP3, and the topmost surface of the filling metal pattern FMP. In the second outer gate electrode OGEb, the topmost surface of the second metal pattern MP2 may be coplanar with the topmost surface of the high-k dielectric layer HK, the topmost surface of the third metal pattern MP3, and the topmost surface of the filling metal pattern FMP. The third metal pattern MP3 may be spaced apart from the gate insulating layer GI by the second metal pattern MP2. In detail, in the first and second outer gate electrodes OGEa and OGEb, the third metal pattern MP3 may be spaced apart from an inner side surface of the gate insulating layer GI by the second metal pattern MP2, e.g., the third metal pattern MP3 may be completely separated from an inner side surface of the high-k dielectric layer HK by the second metal pattern MP2.

The lowermost level of the top surface of the first outer gate electrode OGEa may be a first level LV1. The lowermost level of the top surface of the second outer gate electrode OGEb may be a second level LV2. The first and second levels LV1 and LV2 may be located at substantially the same level. The second outer gate electrode OGEb may have a flat top surface. In other words, each of the topmost surfaces of the second metal pattern MP2, the third metal pattern MP3, and the filling metal pattern FMP may have a flat profile.

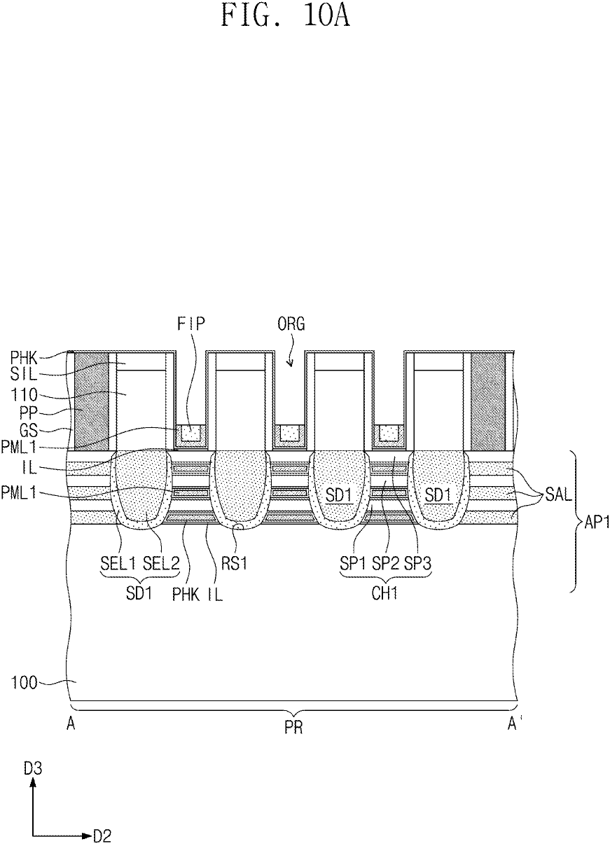

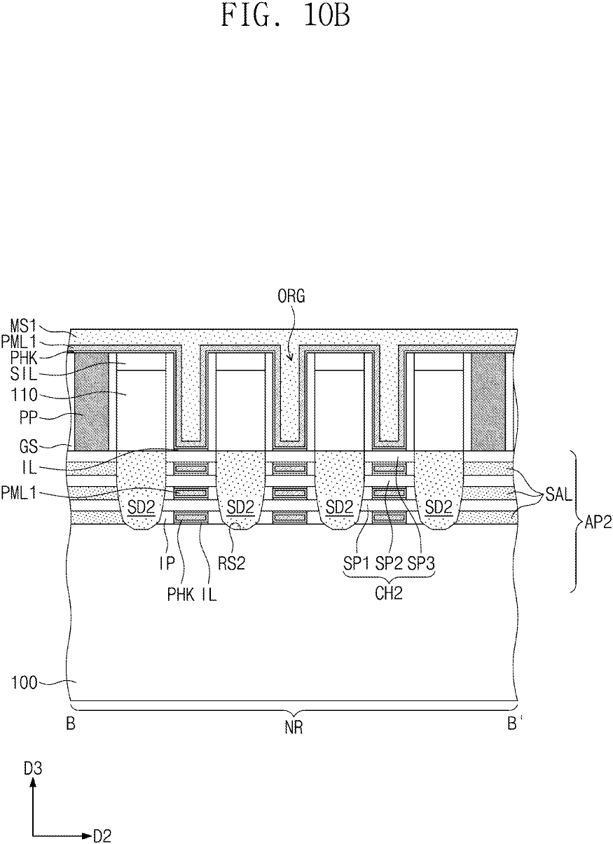

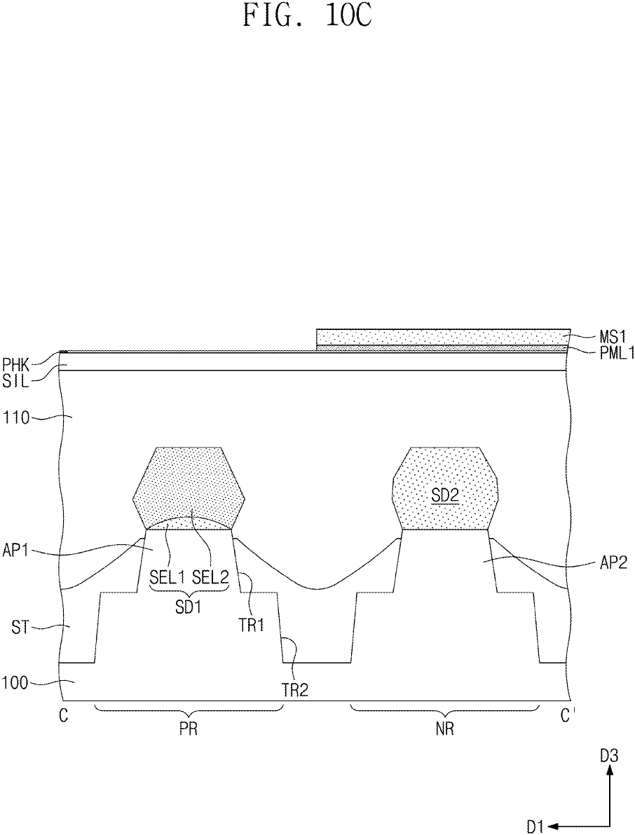

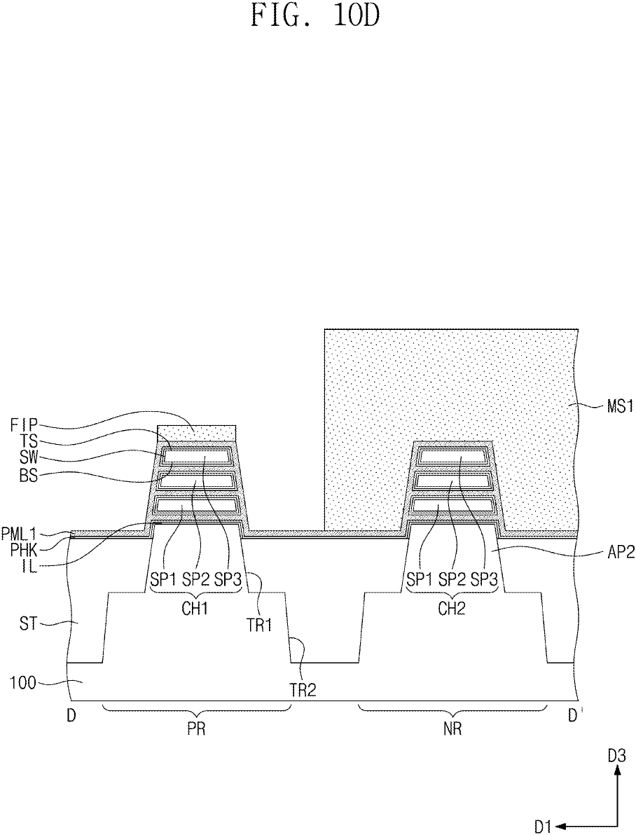

In this case, it may be possible to prevent an upper portion of a preliminary high-k dielectric layer PHK from being slantingly formed by a first preliminary metal pattern PML1, which is left on the second region NR in a chamfering process to be described below, and thereby to prevent the second outer gate electrode OGEb from being over-etched (e.g., see FIGS. 10A to 11D and 14B).

A thickness of the first metal pattern MP1 may be a first thickness T1. A thickness of the second metal pattern MP2 may be a second thickness T2. A thickness of the third metal pattern MP3 may be a third thickness T3. The second thickness T2 may be smaller than each of the first and third thicknesses T1 and T3. In an embodiment, the first thickness T1 may be smaller than the third thickness T3. The first to third thicknesses T1, T2, and T3 may be thicknesses of the first to third metal patterns MP1, MP2, and MP3, respectively, which are measured in the second direction D2. The second thickness T2 in the first region PR may be substantially equal to the second thickness T2 in the second region NR. The third thickness T3 in the first region PR may be substantially equal to the third thickness T3 in the second region NR.

Referring to FIGS. 3A to 3D, the inner gate electrode IGEa on the first region PR may include the first metal pattern MP1. That is, in the first region PR, the first metal pattern MP1 may fill a space between adjacent ones of the first to third semiconductor patterns SP1, SP2, and SP3. In an embodiment, the first metal pattern MP1 may be extended along side surfaces of the first to third semiconductor patterns SP1, SP2, and SP3.

The inner gate electrode IGEb on the second region NR may include the second and third metal patterns MP2 and MP3. In other words, the second and third metal patterns MP2 and MP3 on the second region NR may fill a space between adjacent ones of the first to third semiconductor patterns SP1, SP2, and SP3. For example, on the second region NR, the second metal pattern MP2 may be provided to enclose each of the first to third semiconductor patterns SP1, SP2, and SP3, and the third metal pattern MP3 may be extended along the side surfaces of the first to third semiconductor patterns SP1, SP2, and SP3.

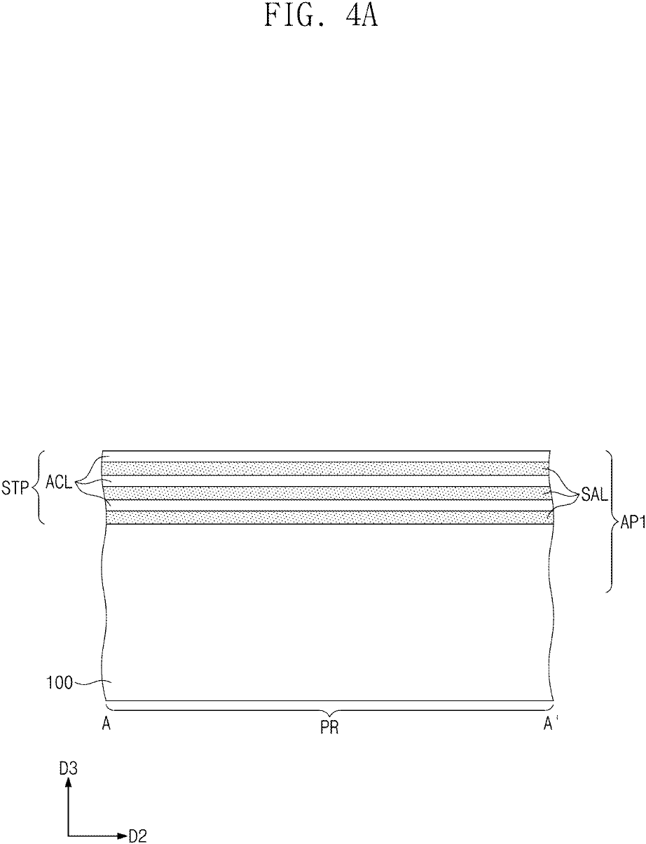

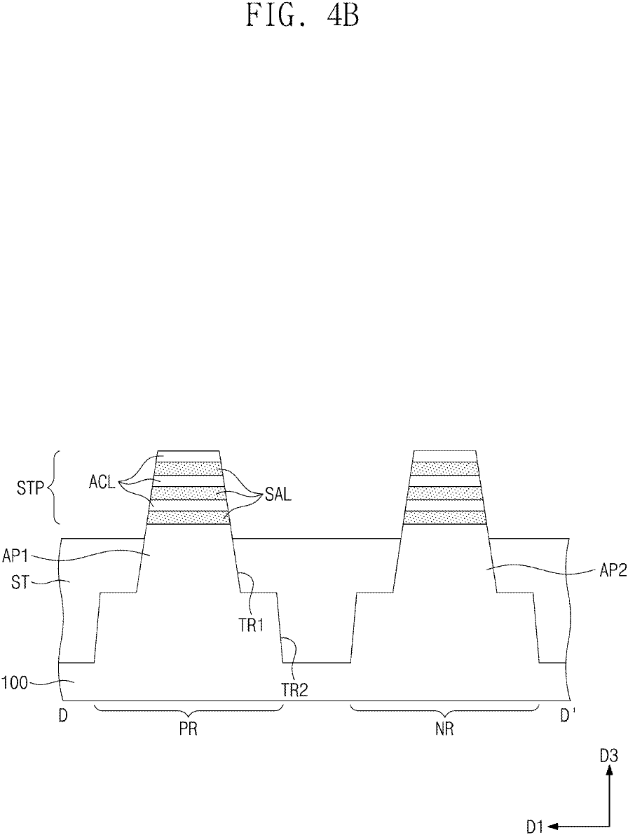

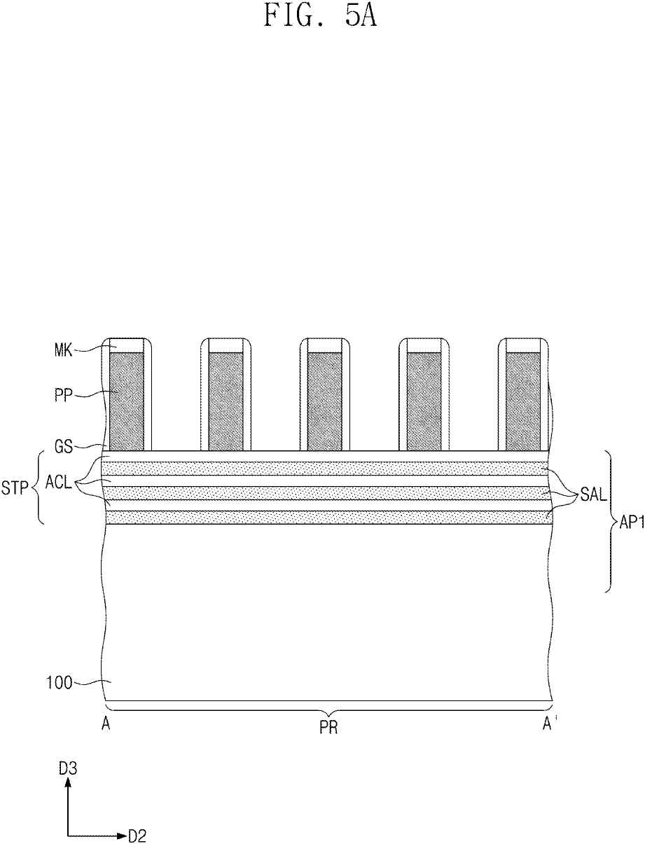

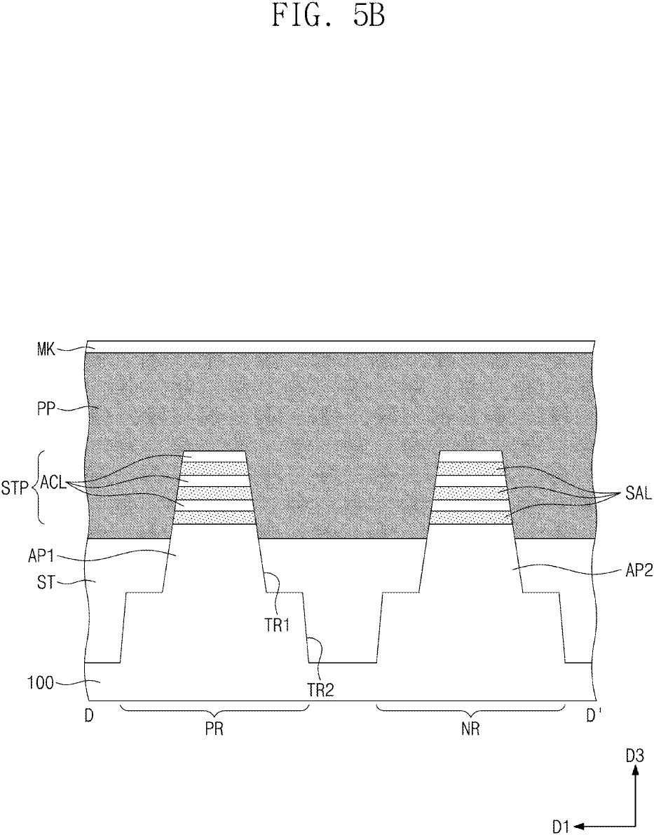

FIGS. 4A to 12D are cross-sectional views of stages in a method of fabricating a semiconductor device according to an embodiment. In detail, FIGS. 4A, 5A, 6A, 7A, 8A, 9A, 10A, 11A, and 12A are cross-sectional views taken along line A-A′ of FIG. 1. FIGS. 7B, 8B, 9B, 10B, 11B, and 12B are cross-sectional views taken along line B-B′ of FIG. 1. FIGS. 7C, 8C, 9C, 10C, 11C, and 12C are cross- views taken along line C-C′ of FIG. 1. FIGS. 4B, 5B, 6D, 7D, 8D, 9D, 10D, 11D, and 12D are cross-sectional views taken along line D-D′ of FIG. 1.

Referring to FIGS. 4A and 4B, the substrate 100 including the first and second regions PR and NR may be provided. The sacrificial layers SAL and active layers ACL may be alternately stacked on the substrate 100. The sacrificial and active layers SAL and ACL may be formed of or include at least one of, e.g., silicon (Si), germanium (Ge), or silicon germanium (SiGe). The material of the active layers ACL may be different from that of the sacrificial layers SAL. For example, the sacrificial layers SAL may be formed of or include silicon germanium (SiGe), and the active layers ACL may be formed of or include silicon (Si). A germanium concentration of each of the sacrificial layers SAL may range from about 10 at% to about 30 at%.

Mask patterns may be respectively formed on the first and second regions PR and NR of the substrate 100. The mask patterns may be line- or bar-shaped patterns that extend in the second direction D2.

A first patterning process, in which the mask patterns are used as an etch mask, may be performed to form the first trench TR1 defining the first and second active patterns AP1 and AP2. The first and second active patterns AP1 and AP2 may be formed on the first and second regions PR and NR, respectively. A stacking pattern STP may be formed on each of the first and second active patterns AP1 and AP2. The stacking pattern STP may include the sacrificial layers SAL and the active layers ACL, which are alternatingly stacked. The stacking pattern STP may be formed along with the first and second active patterns AP1 and AP2, during the first patterning process.

A second patterning process may be performed on the substrate 100 to form the second trench TR2 defining the first and second regions PR and NR. The second trench TR2 may be formed to have a depth that is larger than that of the first trench TR1.

The device isolation layer ST may be formed on the substrate 100 to fill the first and second trenches TR1 and TR2. For example, an insulating layer may be formed on the substrate 100 to cover the first and second active patterns AP1 and AP2. The device isolation layer ST may be formed by recessing the insulating layer until the sacrificial layers SAL are exposed.

Referring to FIGS. 5A and 5B, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged, with a specific pitch, in the second direction D2.

In detail, the formation of the sacrificial patterns PP may include forming a sacrificial layer on the substrate 100, forming hard mask patterns MK on the sacrificial layer, and patterning the sacrificial layer using the hard mask patterns MK as an etch mask. The sacrificial layer may be formed of or include poly silicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or include at least one of, e.g., SiCN, SiCON, or SiN. Alternatively, the gate spacer layer may include at least two layers formed of at least one of SiCN, SiCON, or SiN; that is, the gate spacer layer may have a multi-layered structure.

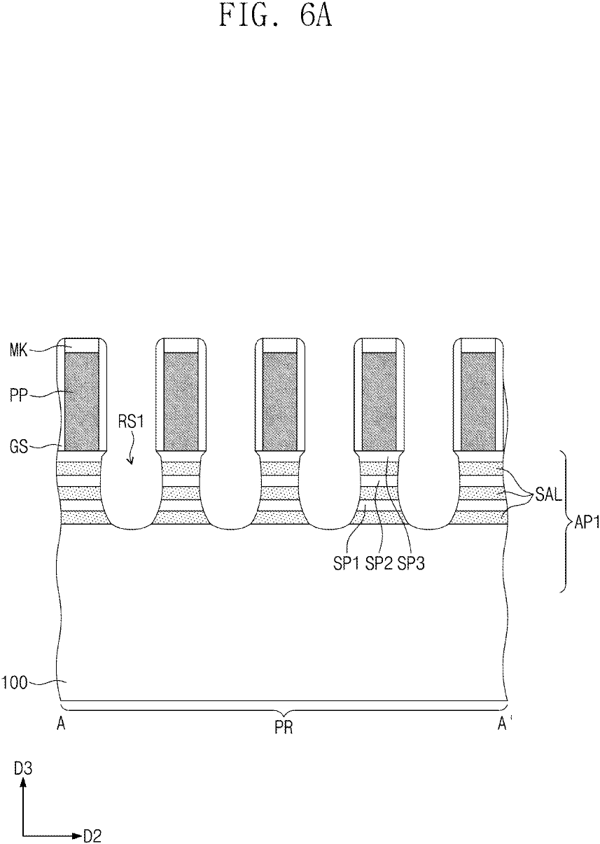

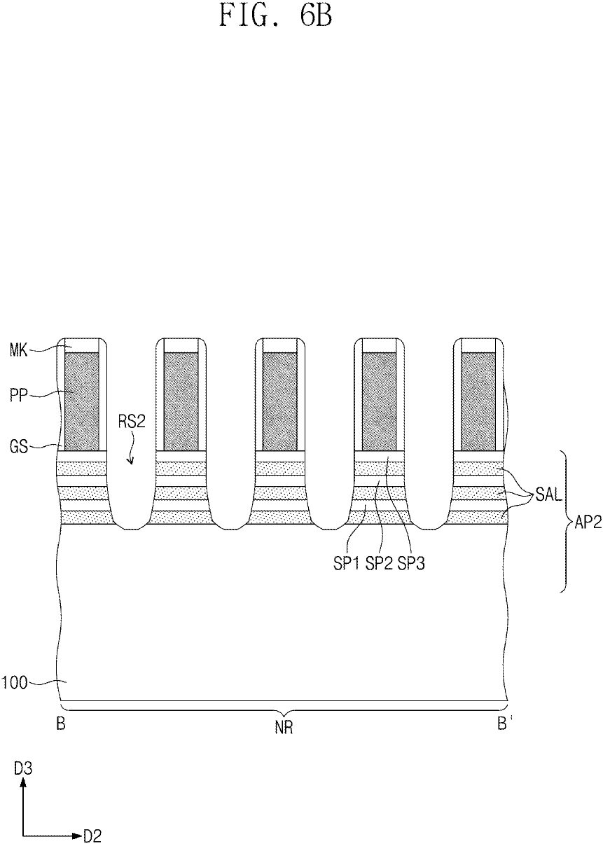

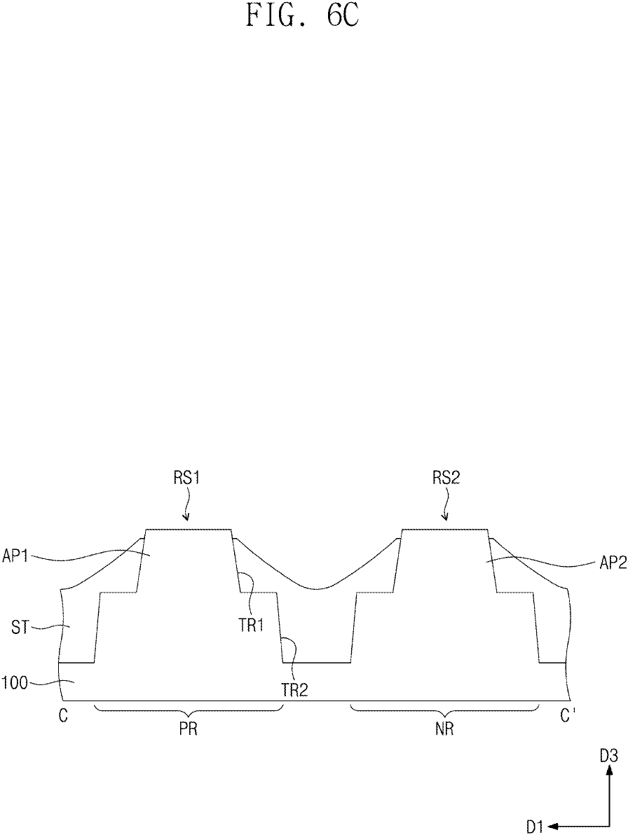

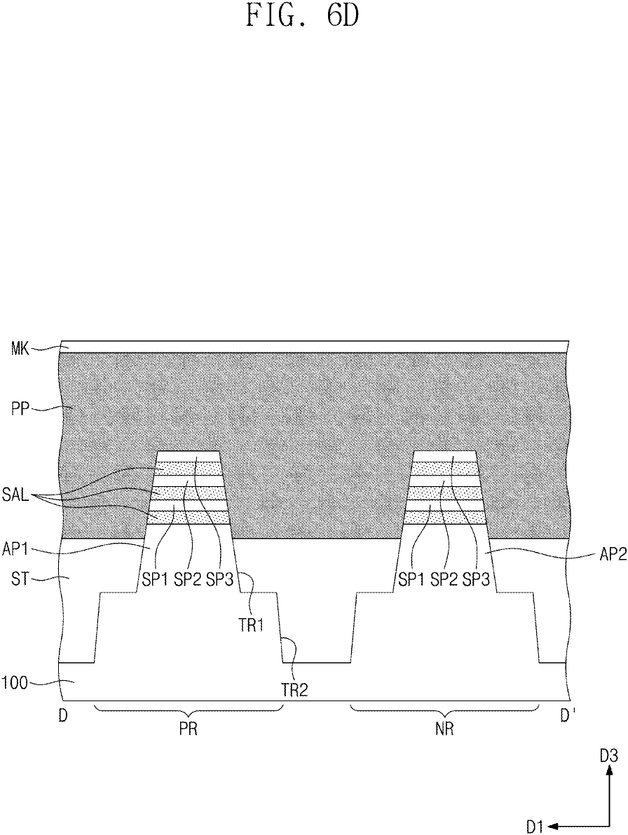

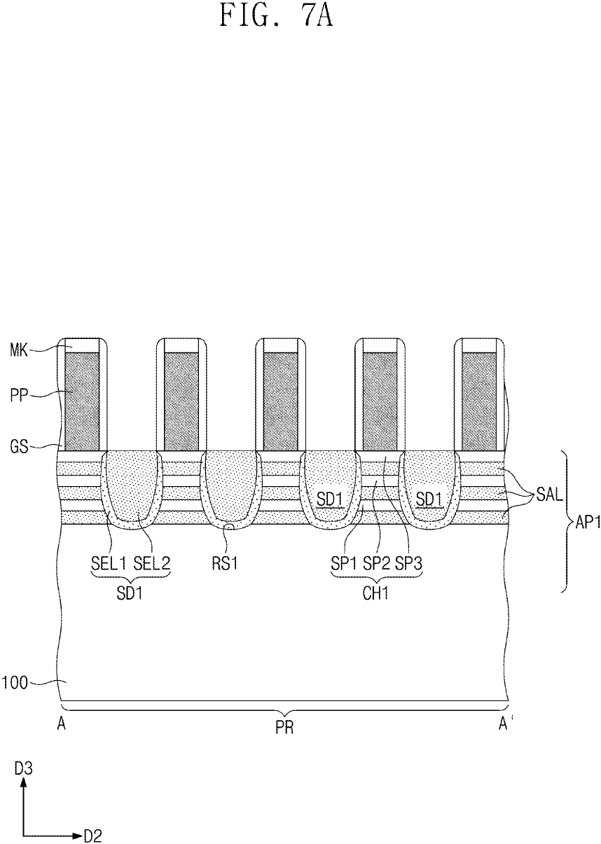

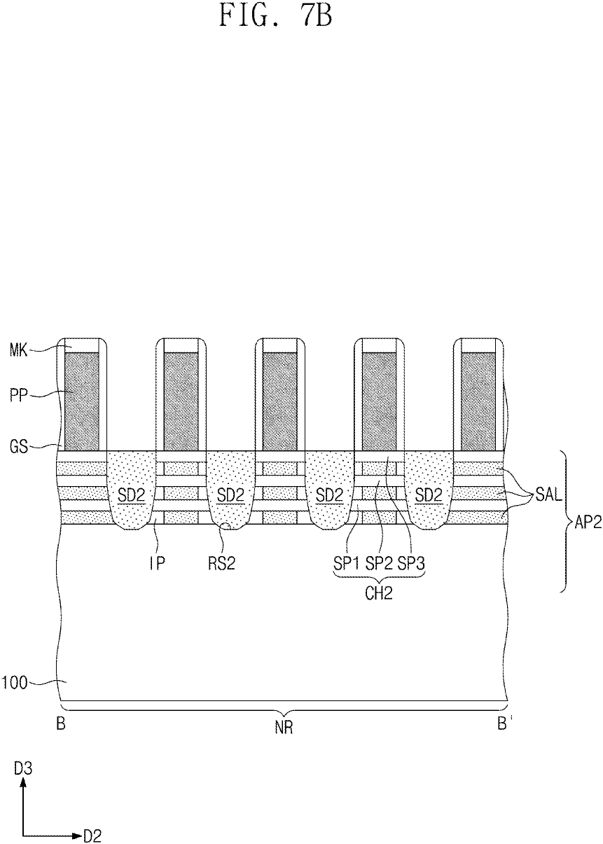

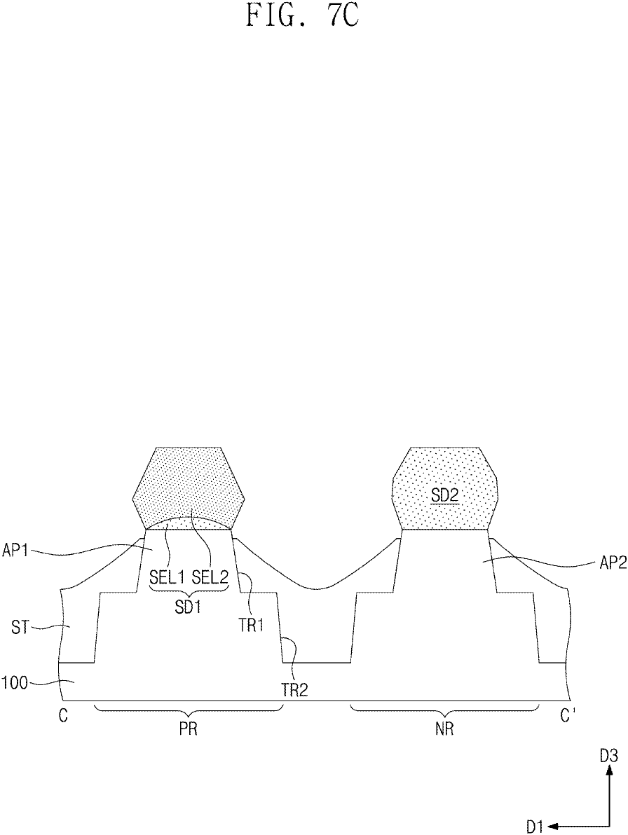

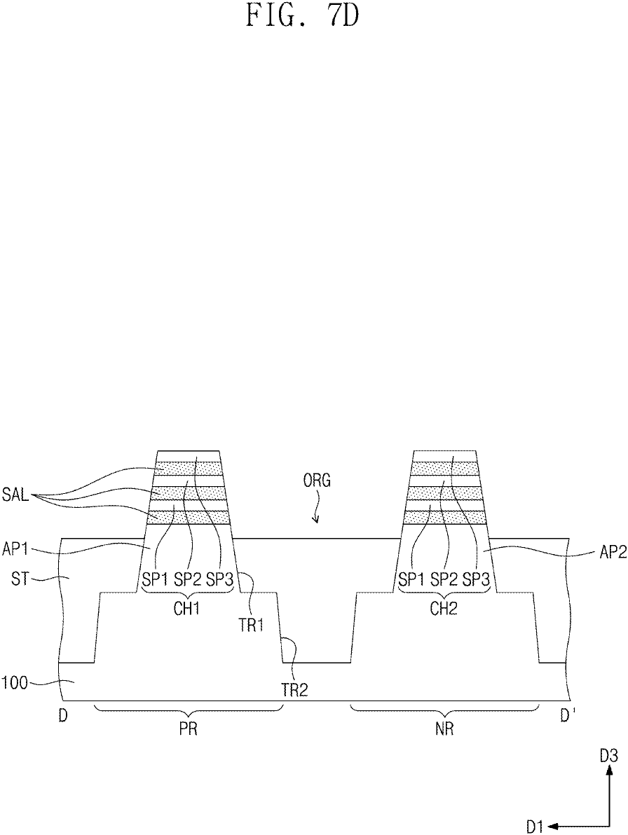

Referring to FIGS. 6A to 6D, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may be further recessed at both sides of each of the first and second active patterns AP1 and AP2 (e.g., see FIG. 6C).

In detail, the first recesses RS1 may be formed by etching the stacking pattern STP on the first active pattern AP1 using the hard mask patterns MK and the gate spacers GS as an etch mask. Each of the first recesses RS1 may be formed between each pair of the sacrificial patterns PP. The second recesses RS2 in the stacking pattern STP on the second active pattern AP2 may be formed by the same method as that for the first recesses RS1. The first to third semiconductor patterns SP1, SP2, and SP3, which are sequentially stacked between adjacent ones of the first recesses RS1, may be formed from the active layers ACL. The first to third semiconductor patterns SP1, SP2, and SP3, which are sequentially stacked between adjacent ones of the second recesses RS2, may be formed from the active layers ACL.

Referring to FIGS. 7A to 7D, the first source/drain patterns SD1 may be formed in the first recesses RS1, respectively. In detail, the first semiconductor layer SEL1 may be formed by performing a first SEG process using an inner surface of the first recess RS1 as a seed layer. The first semiconductor layer SEL1 may be grown using the first to third semiconductor patterns SP1, SP2, and SP3 and the substrate 100, which are exposed through the first recesses RS1, as a seed. For example, the first SEG process may include a chemical vapor deposition (CVD) process or a molecular beam epitaxy (MBE) process.

The first semiconductor layer SEL1 may be formed of or include a semiconductor material (e.g., SiGe) having a lattice constant greater than that of the substrate 100. The first semiconductor layer SEL1 may be formed to have a relatively low germanium concentration. In another embodiment, the first semiconductor layer SEL1 may be provided to contain only silicon (Si) and not germanium (Ge). The germanium concentration of the first semiconductor layer SEL1 may range from 0 at% to 10 at%.

The second semiconductor layer SEL2 may be formed by performing a second SEG process on the first semiconductor layer SEL1. The second semiconductor layer SEL2 may be formed to completely fill the first recess RS1. The second semiconductor layer SEL2 may be provided to have a relatively high germanium concentration. For example, the germanium concentration of the second semiconductor layer SEL2 may range from 30 at% to 70 at%.

The first and second semiconductor layers SEL1 and SEL2 may constitute the first source/drain pattern SD1. The first and second semiconductor layers SEL1 and SEL2 may be doped with impurities in situ during the first and second SEG processes. Alternatively, the first source/drain pattern SD1 may be doped with impurities, after the formation of the first source/drain pattern SD1. The first source/drain pattern SD1 may be doped to have the first conductivity type (e.g., a p-type).

The second source/drain patterns SD2 may be formed in the second recesses RS2, respectively. In detail, the second source/drain pattern SD2 may be formed by performing a SEG process using an inner surface of the second recess RS2 as a seed layer. In an embodiment, the second source/drain pattern SD2 may be formed of or include the same semiconductor material (e.g., Si) as the substrate 100. The second source/drain pattern SD2 may be doped to have a second conductivity type (e.g., n-type). The inner spacers IP may be respectively formed between the second source/drain pattern SD2 and the sacrificial layers SAL.

The first to third semiconductor patterns SP1, SP2, and SP3 between adjacent ones of the first recesses RS1 may constitute the first channel pattern CH1. The first to third semiconductor patterns SP1, SP2, and SP3 between adjacent ones of the second recesses RS2 may constitute the second channel pattern CH2.

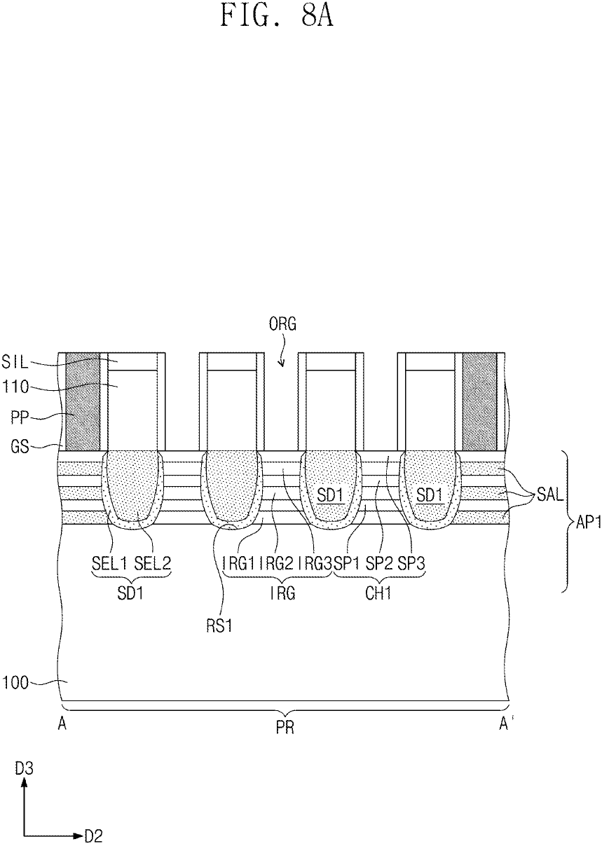

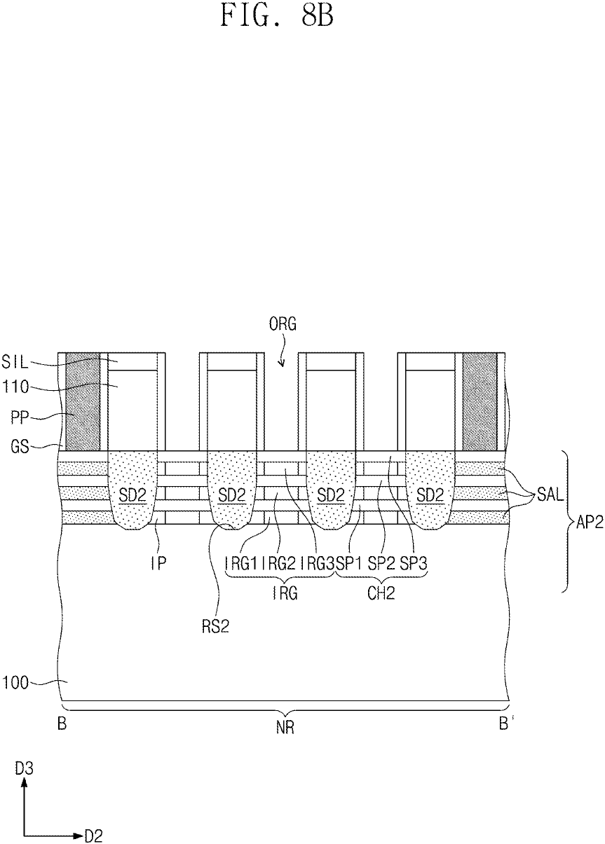

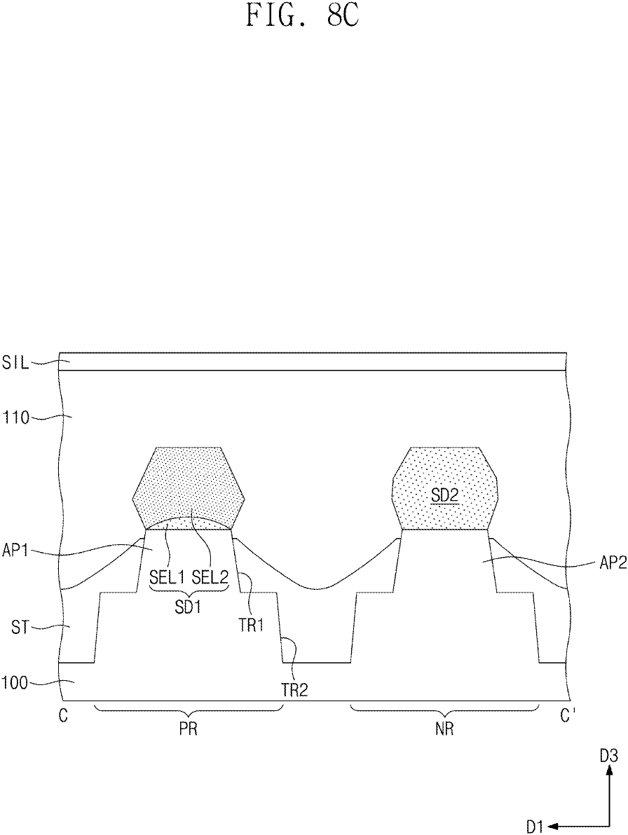

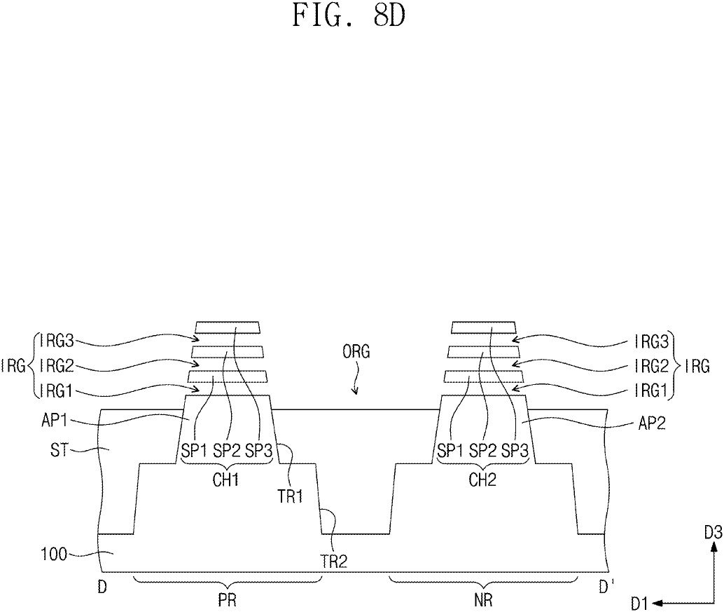

Referring to FIGS. 8A to 8D, the first interlayer insulating layer 110 may be formed to cover the first and second source/drain patterns SD1 and SD2, the hard mask patterns MK, and the gate spacers GS. In an embodiment, the first interlayer insulating layer 110 may include, e.g., a silicon oxide layer.

The first interlayer insulating layer 110 may be planarized to expose the top surfaces of the sacrificial patterns PP. The planarization of the first interlayer insulating layer 110 may be performed using an etch-back or chemical mechanical polishing (CMP) process. All of the hard mask patterns MK may be removed during the planarization process. Accordingly, the first interlayer insulating layer 110 may have a top surface that is coplanar with the top surfaces of the sacrificial patterns PP and the top surfaces of the gate spacers GS.

An upper portion of the first interlayer insulating layer 110 may be recessed. A sacrificial insulating layer SIL may be formed in an empty space, which is formed by recessing the first interlayer insulating layer 110. In an embodiment, the sacrificial insulating layer SIL may be formed of or include, e.g., silicon nitride. The sacrificial insulating layer SIL may prevent the first interlayer insulating layer 110 from being etched in a process of recessing upper portions of the first and second outer gate electrodes OGEa and OGEb to be described below, and this may make it possible to prevent a failure from occurring in a subsequent process.

In an embodiment, the exposed sacrificial patterns PP may be selectively removed. Since the sacrificial patterns PP are removed, outer regions ORG may be formed to expose the first and second channel patterns CH1 and CH2, respectively (e.g., see FIG. 8D).

The sacrificial layers SAL exposed through the outer region ORG may be selectively removed to form inner regions IRG (e.g., see FIG. 8D). In detail, an etching process of selectively etching only the sacrificial layers SAL may be performed to remove only the sacrificial layers SAL and to leave the first to third semiconductor patterns SP1, SP2, and SP3. The etching process may be chosen to have a high etch rate for a material (e.g., SiGe) having a relatively high germanium concentration. For example, the etching process may have a high etch rate for silicon-germanium whose germanium concentration is higher than 10 at%.

The sacrificial layers SAL on the first and second regions PR and NR may be removed, during the etching process. The etching process may be a wet etching process. An etchant material, which is used in the etching process, may be chosen to quickly remove the sacrificial layer SAL having a relatively high germanium concentration. Meanwhile, during the etching process, the first source/drain pattern SD1 of the first region PR may be protected by the first semiconductor layer SEL1 having a relatively low germanium concentration.

Referring back to FIG. 8D, since the sacrificial layers SAL are selectively removed, only the stacked first to third semiconductor patterns SP1, SP2, and SP3 may be left on each of the first and second active patterns AP1 and AP2. Empty regions, which are formed by removing the sacrificial layers SAL, may form first, second, and third inner regions IRG1, IRG2, and IRG3, respectively.

In detail, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

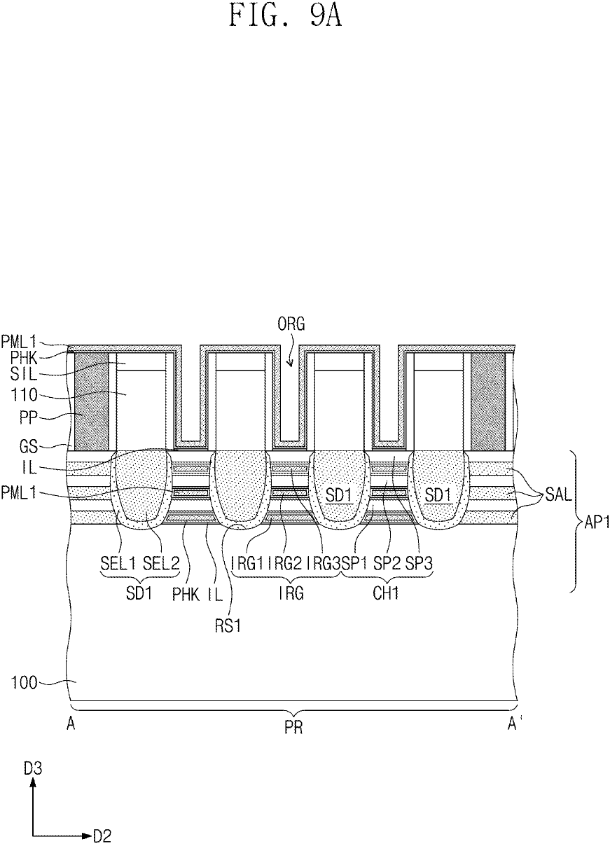

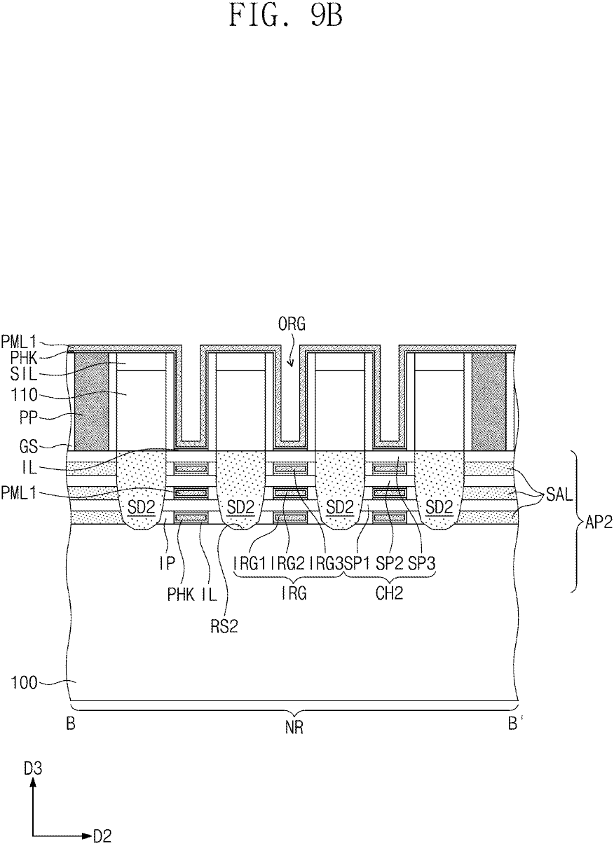

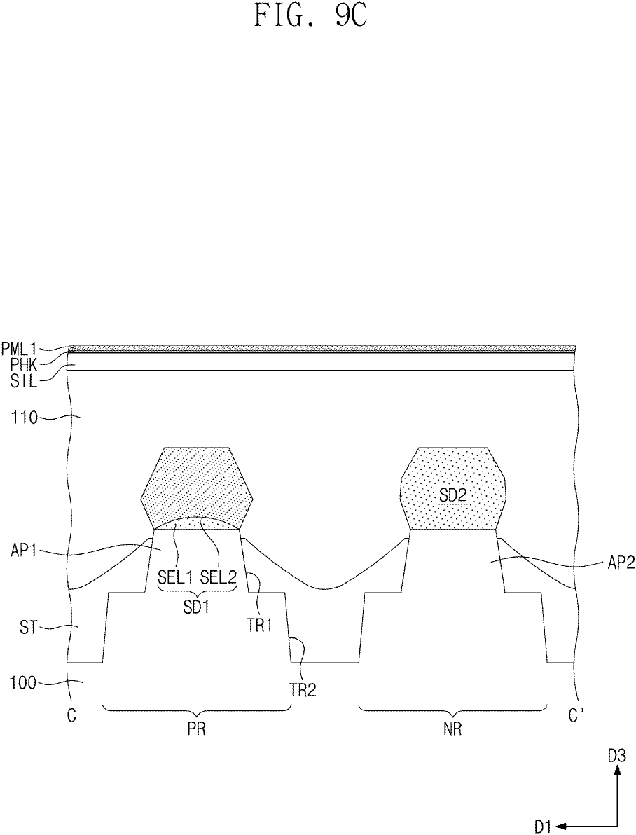

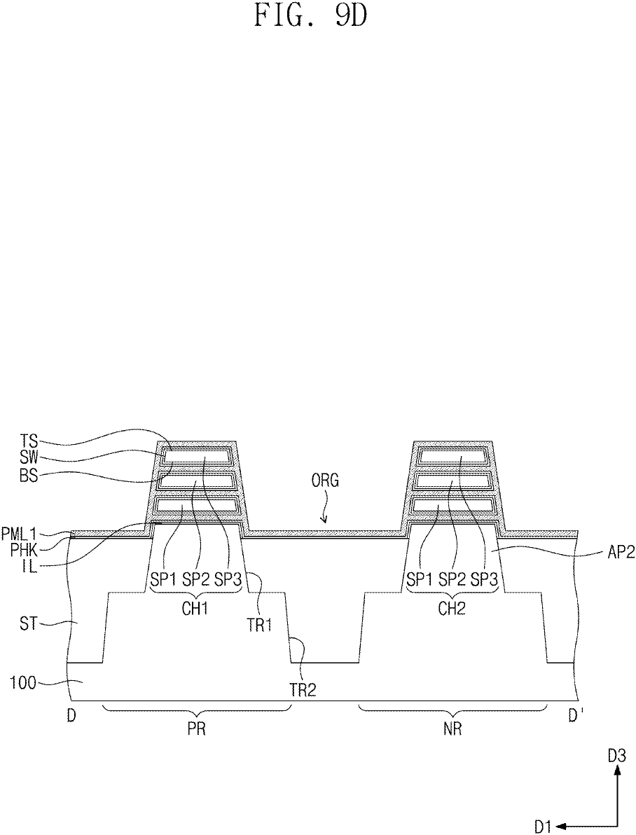

Referring to FIGS. 9A to 9D, the interface layer IL may be conformally formed in the first to third inner regions IRG1, IRG2, and IRG3, and the outer regions ORG. In an embodiment, the interface layer IL may be formed of or include, e.g., silicon oxide. The preliminary high-k dielectric layer PHK may be conformally formed on the interface layer IL. The preliminary high-k dielectric layer PHK may be formed of or include at least one of high-k dielectric materials. The preliminary high-k dielectric layer PHK may be extended along an inner side surface of each of the first to third inner regions IRG1, IRG2, and IRG3 and the outer region ORG and a top surface of the sacrificial insulating layer SIL. The preliminary high-k dielectric layer PHK may be extended along the top surface of the device isolation layer ST.

The first preliminary metal pattern PML1 may be conformally formed on the preliminary high-k dielectric layer PHK. The first preliminary metal pattern PML1 may be formed of or include a p-type work function metal having a relatively-high work function. The first preliminary metal pattern PML1 may fill the first to third inner regions IRG1, IRG2, and IRG3. The first preliminary metal pattern PML1 may be extended along the inner side surface of the outer region ORG and the top surface of the sacrificial insulating layer SIL.

Referring to FIGS. 10A to 10D, a gapfill pattern FIP may be formed on the first region PR, and a first mask MS1 may be formed on the second region NR. The gapfill pattern FIP may fill a portion of each of the outer regions ORG of the first region PR. A top surface of the gapfill pattern FIP may be lower than a top surface of the first interlayer insulating layer 110. The gapfill pattern FIP may be formed of or include at least one of spin-on-hard mask (SOH) materials. The first mask MS1 may cover the second region NR. The first mask MS1 may be formed to fully fill the outer regions ORG of the second region NR. The first mask MS1 may be formed to expose the first region PR.

The first preliminary metal pattern PML1 may be chamfered using the first mask MS1 and the gapfill pattern FIP as an etch mask, e.g., portions of the first preliminary metal pattern PML1 may be removed to expose the preliminary high-k dielectric layer PHK on the gate spacers GS. As a result of the chamfering process, the first preliminary metal pattern PML1, which is provided in the outer region ORG of the first region PR, may be recessed to have a lowered top surface, e.g., relative to the topmost surface of the preliminary high-k dielectric layer PHK. The recessed top surface of the first preliminary metal pattern PML1 may be located at a level lower than the top surface of the first interlayer insulating layer 110.

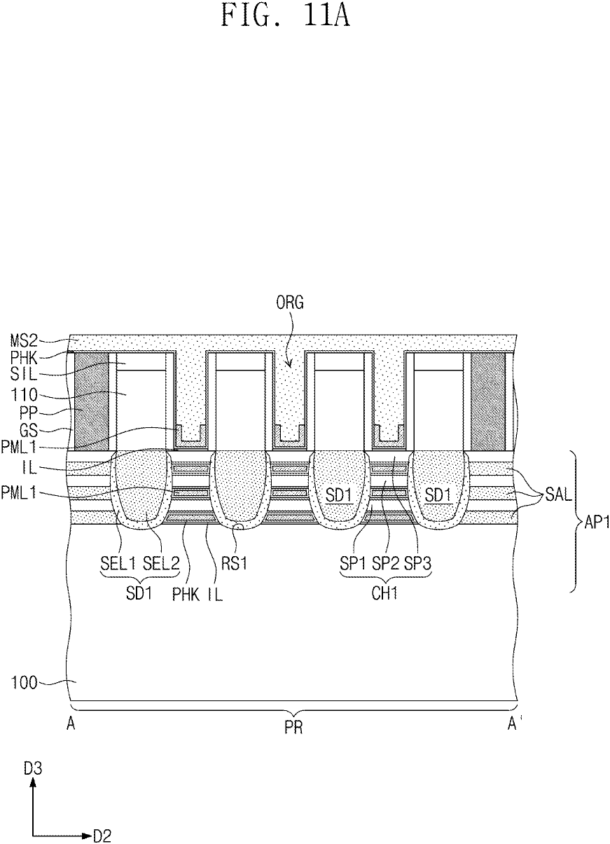

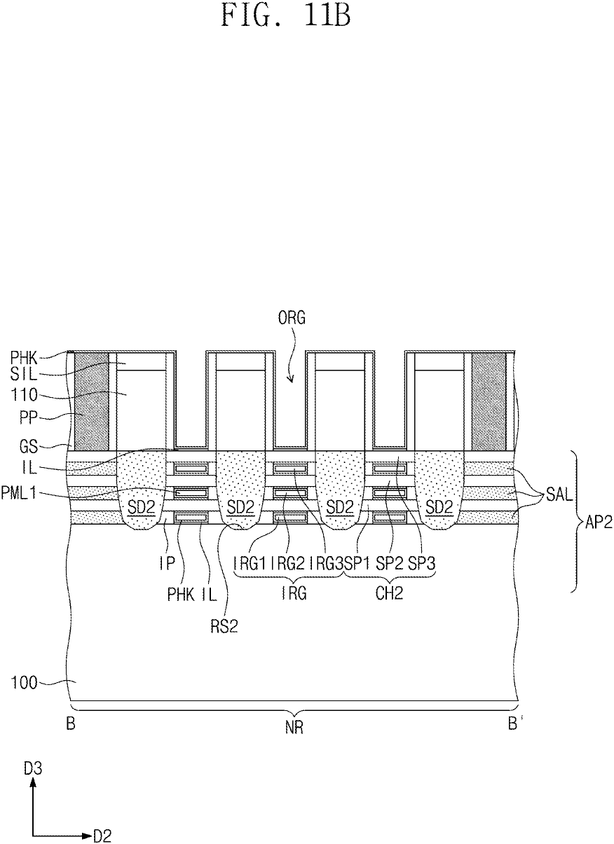

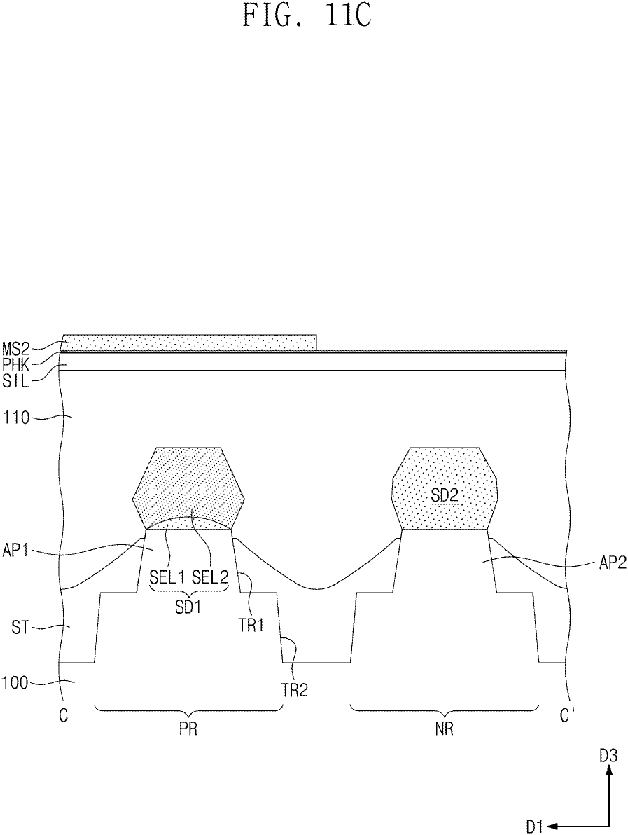

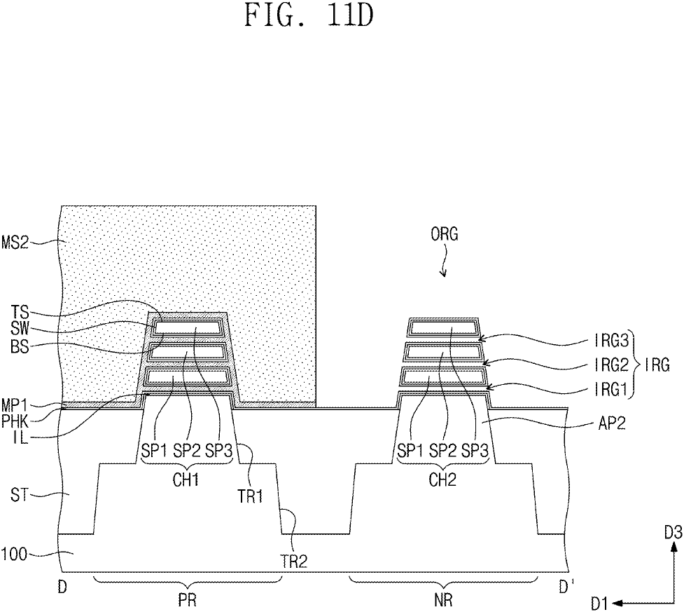

Referring to FIGS. 11A to 11D, the gapfill pattern FIP and the first mask MS1 may be removed, and then, a second mask MS2 may be formed on the first region PR. The second mask MS2 may be formed to cover the first region PR and to expose the second region NR.

The first preliminary metal pattern PML1 on the second region NR may be removed using the second mask MS2 as an etch mask. Thus, the first preliminary metal pattern PML1 may be removed from the first to third inner regions IRG1, IRG2, and IRG3 and the outer regions ORG on the second region NR. As a result, the first metal pattern MP1 may be formed on the first region PR.

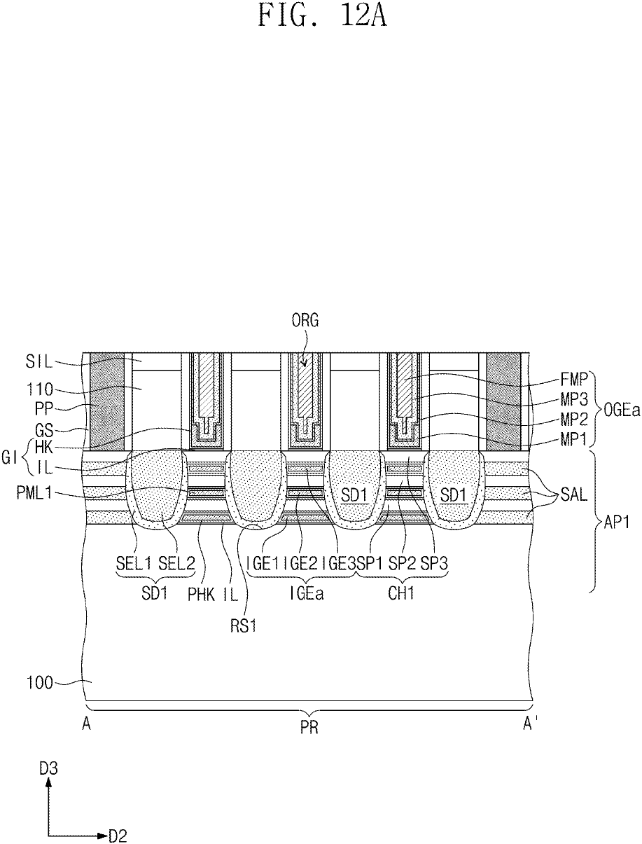

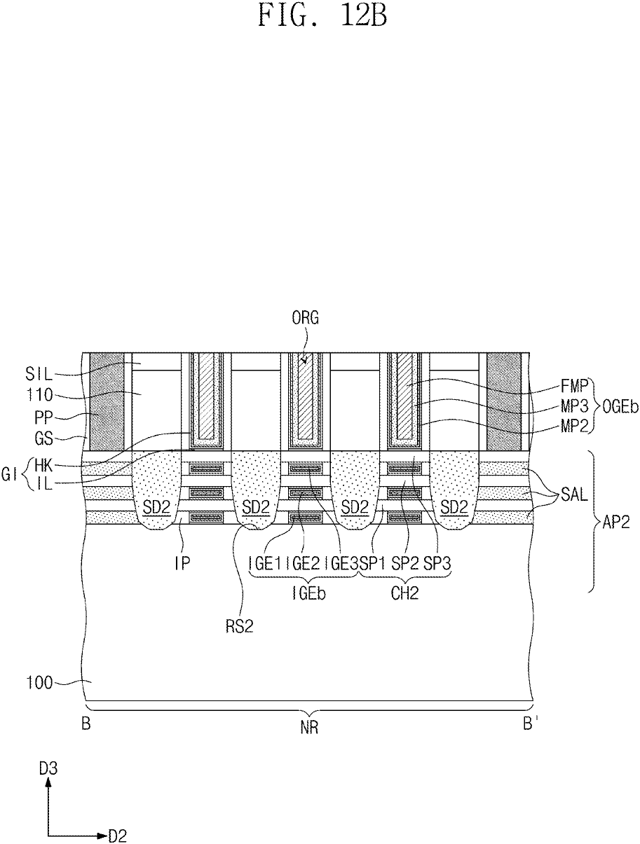

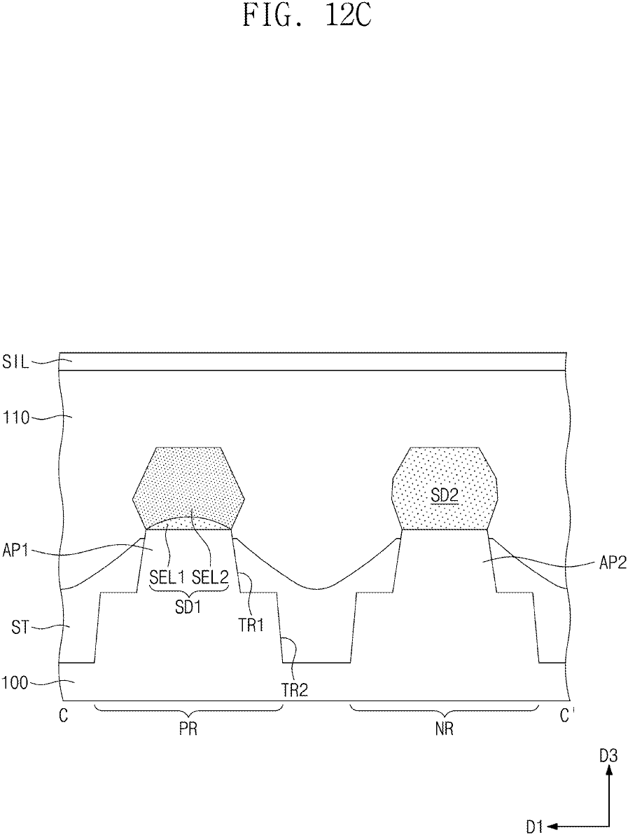

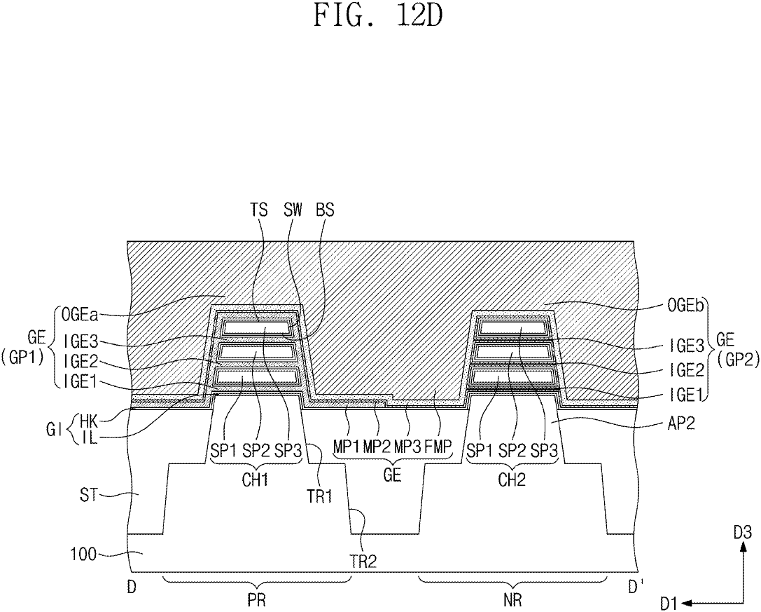

Referring to FIGS. 12A to 12D, a second preliminary metal pattern may be conformally formed on the outer regions ORG of the first region PR, the outer regions ORG of the second region NR, and the first to third inner regions IRG1, IRG2, and IRG3. In an embodiment, the second preliminary metal pattern may be formed of or include, e.g., titanium nitride (TiN). The second preliminary metal pattern may be extended along the inner side surface of the outer regions ORG and the top surface of the sacrificial insulating layer SIL. The second preliminary metal pattern may be extended along the inner side surface of each of the first to third inner regions IRG1, IRG2, and IRG3 of the second region NR.

A third preliminary metal pattern may be conformally formed on the second preliminary metal pattern. The third preliminary metal pattern may be formed of or include an n-type work function metal. The third preliminary metal pattern may be extended along the inner side surfaces of the outer regions ORG and the top surface of the sacrificial insulating layer SIL. The third preliminary metal pattern may fill remaining spaces of the first to third inner regions IRG1, IRG2, and IRG3 of the second region NR.

A preliminary filling metal pattern may be formed on the third preliminary metal pattern. The preliminary filling metal pattern may be formed to fill remaining portions of the outer regions ORG. In an embodiment, the preliminary filling metal pattern may be formed of or include, e.g., titanium nitride (TiN). In another embodiment, the preliminary filling metal pattern may be formed of or include at least one of low resistance metals (e.g., aluminum (Al), tungsten (W), titanium (Ti), and tantalum (Ta)).

A planarization process may be performed to remove a portion of each of the preliminary filling metal pattern, the third preliminary metal pattern, the second preliminary metal pattern, and the preliminary high-k dielectric layer PHK, and to expose the top surface of the sacrificial insulating layer SIL. The high-k dielectric layer HK, the second metal pattern MP2, the third metal pattern MP3, and the filling metal pattern FMP may be formed by the planarization process. As a result, the first outer gate electrode OGEa may be formed in the outer region ORG on the first region PR, and the second outer gate electrode OGEb may be formed in the outer region ORG on the second region NR.

Referring back to FIGS. 1 and 2A to 2D, an upper portion of each of the first and second outer gate electrodes OGEa and OGEb may be recessed. The gate capping pattern GP may be formed in an empty space, which is formed by recessing the first and second outer gate electrodes OGEa and OGEb. A planarization process may be performed to expose the top surface of the first interlayer insulating layer 110. As a result, the sacrificial insulating layer SIL may be fully removed, and the top surface of the gate capping pattern GP may be coplanar with the top surface of the first interlayer insulating layer 110.

The second interlayer insulating layer 120 may be formed on the first interlayer insulating layer 110. The second interlayer insulating layer 120 may include, e.g., a silicon oxide layer. The active contacts AC may be formed to penetrate the second interlayer insulating layer 120 and the first interlayer insulating layer 110 and to be electrically connected to the first and second source/drain patterns SD1 and SD2. The gate contact GC may be formed to penetrate the second interlayer insulating layer 120 and the gate capping pattern GP and to be electrically connected to the gate electrode GE.

A pair of the dividing structures DB may be formed at both sides of the logic cell LC. The division structure DB may be provided to penetrate the second interlayer insulating layer 120 and the gate electrode GE, and may be extended into the active pattern AP1 or AP2. The division structure DB may be formed of or include an insulating material (e.g., silicon oxide or silicon nitride).

The third interlayer insulating layer 130 may be formed on the active contacts AC and the gate contacts GC. The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

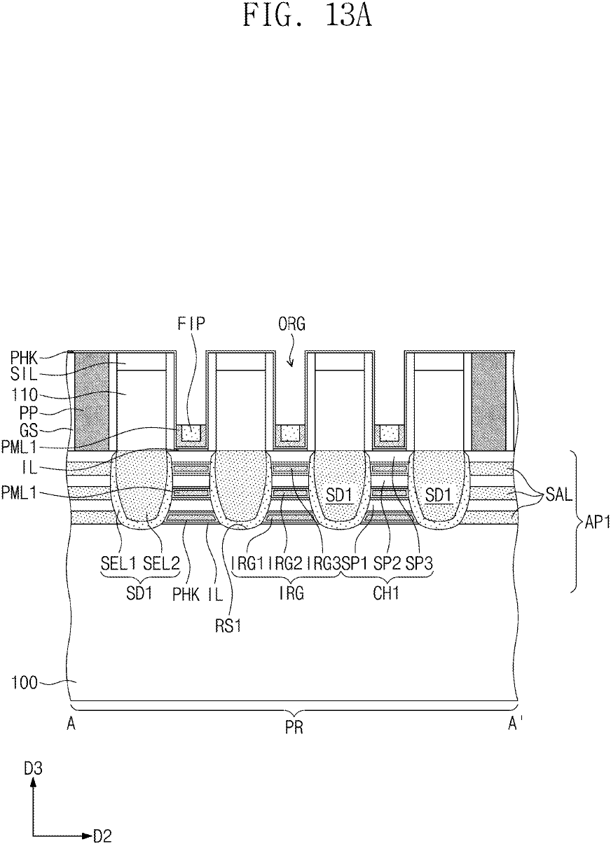

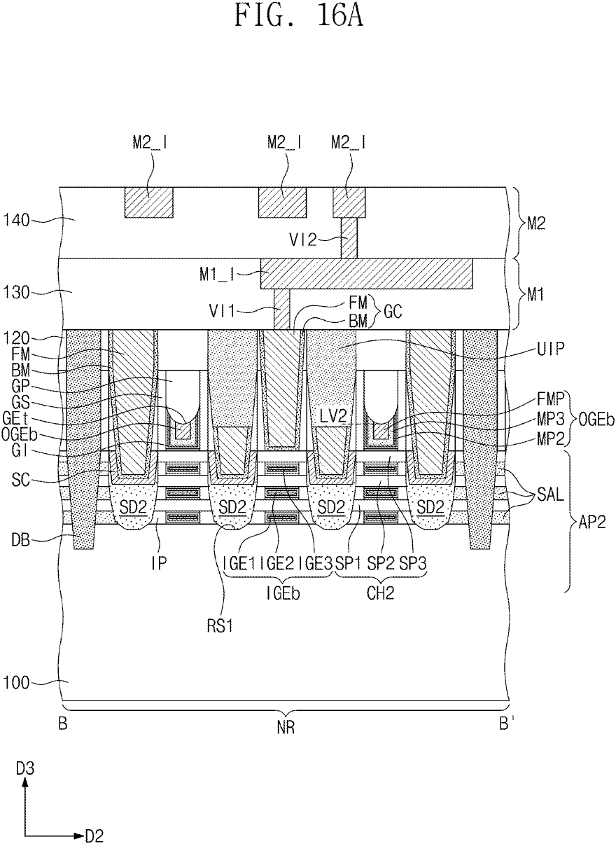

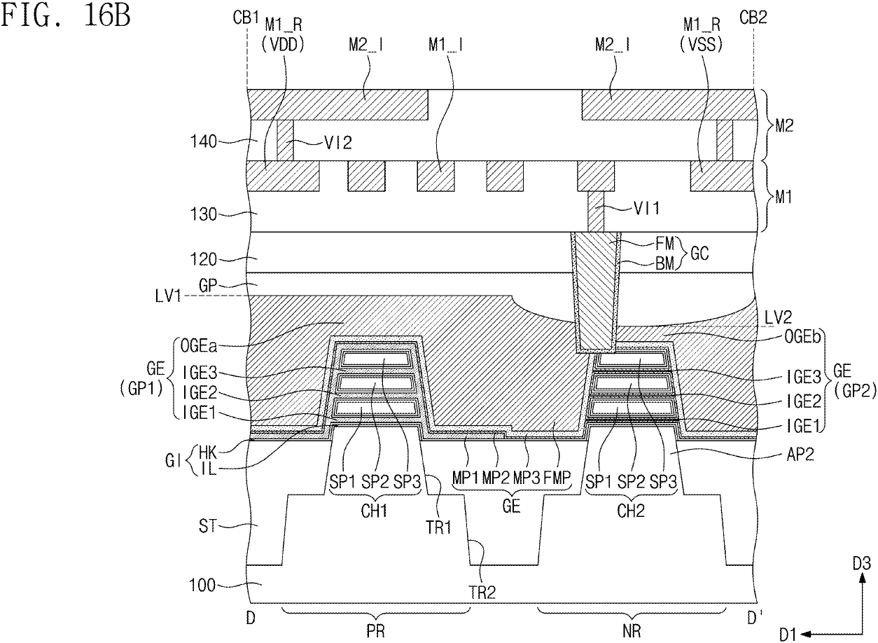

FIGS. 13A to 16B are cross-sectional views illustrating stages in a method of fabricating a semiconductor device according to a comparative example. FIGS. 13A, 14A, and 16A are cross-sectional views corresponding to line A-A′ of FIG. 1. FIGS. 13B, 14B, and 15 are cross-sectional views corresponding to line B-B′ of FIG. 1. FIG. 16B is a cross-sectional view corresponding to line D-D′ of FIG. 1. In the following description of the comparative example, an element previously described with reference to FIGS. 1, 2A to 2D, and 4A to 12D may be identified by the same reference number without repeating an overlapping description thereof, for concise description.

Referring to FIGS. 13A and 13B, after the process described with reference to FIGS. 9A to 9D, if the gapfill pattern FIP were to be formed on both the first and second regions PR and NR, so the first preliminary metal pattern PML1 were to be chamfered using the gapfill pattern FIP as an etch mask in both the first and second regions PR and NR (i.e., without a mask covering the second region NR), the first preliminary metal pattern PML1 (in the outer regions ORG of both the first and second regions PR and NR) would have been recessed to have a lowered top surface in both the first and second regions PR and NR.

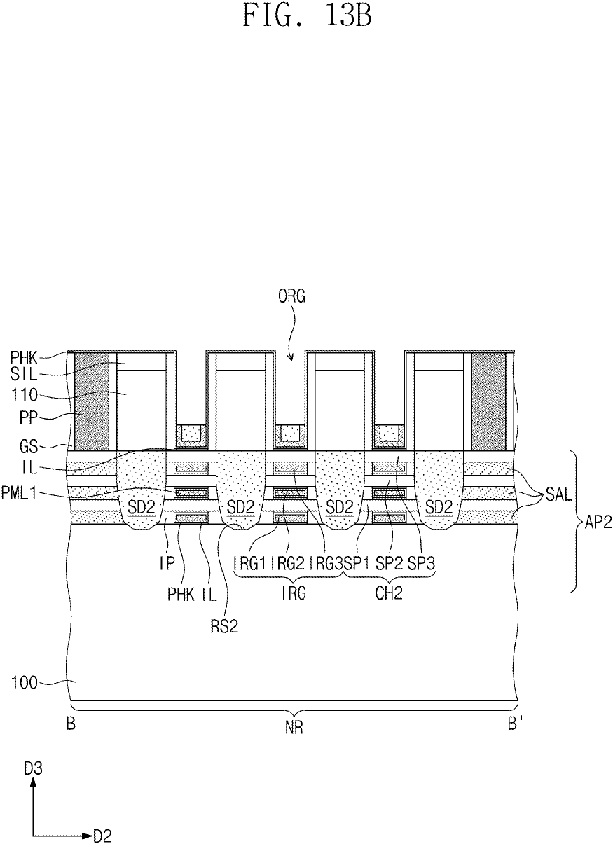

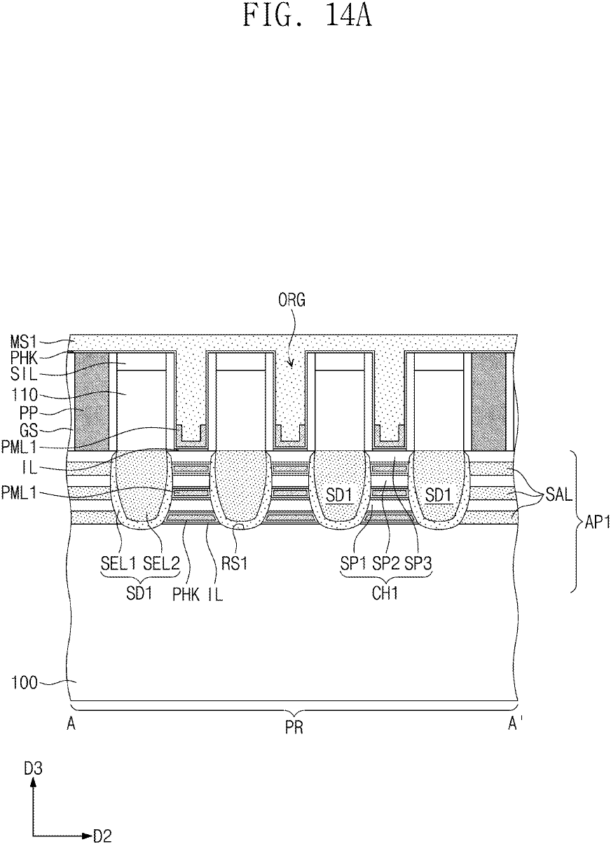

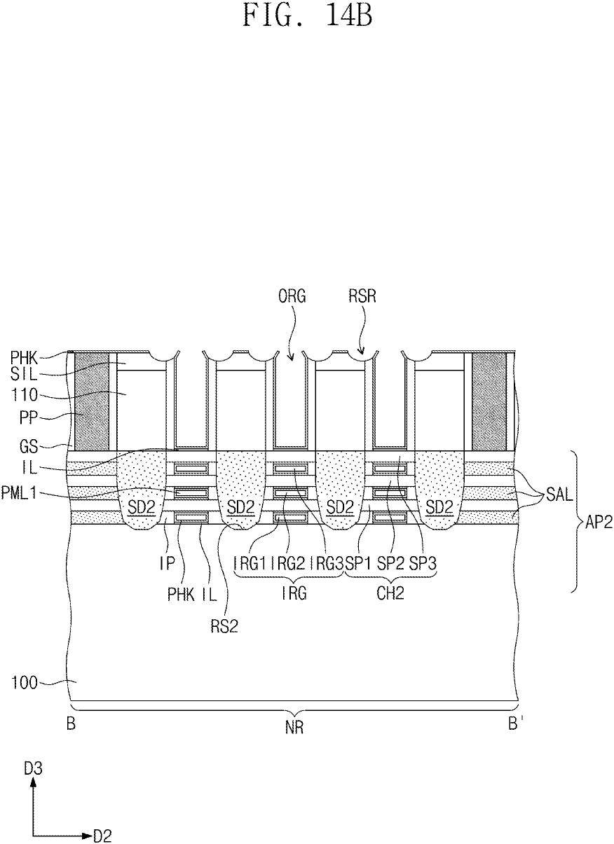

Referring to FIGS. 14A and 14B, the first mask MS1 may be formed on the first region PR. The first mask MS1 may fill remaining portions of the outer regions ORG of the first region PR. The first mask MS1 may be formed to expose the second region NR. The first preliminary metal pattern PML1 may be removed using the first mask MS1 as an etch mask. Here, since the preliminary high-k dielectric layer PHK and the sacrificial insulating layer SIL on the second region NR would have been etched (since the second region NR were not covered with a mask in a previous processing stage), an upper portion of the sacrificial insulating layer SIL would have been recessed to form a recess region RSR, and an upper portion of the preliminary high-k dielectric layer PHK would have been inclined, thereby narrowing an entrance of the outer region ORG of the second region NR.

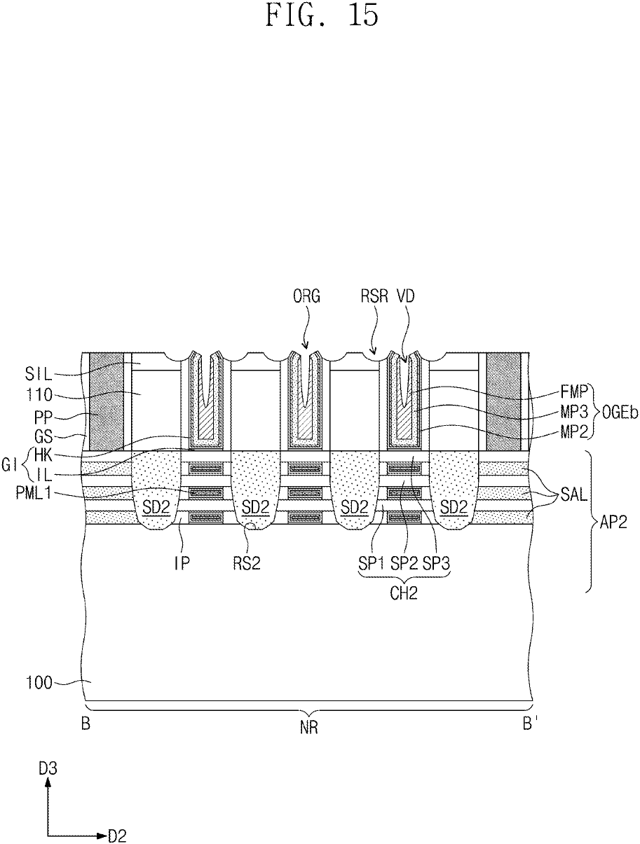

Referring to FIG. 15, if a process were to be performed in the same manner as the process described with reference to FIGS. 12A to 12D, due to the inclined upper portion of the preliminary high-k dielectric layer PHK and the narrowed entrance of the outer region ORG, it would have been difficult to deposit a metallic material in the outer region ORG. Therefore, a void VD could have been formed in a center portion of the second outer gate electrode OGEb.

Referring to FIGS. 16A and 16B, if a process were to be performed in the same manner as described with reference to FIGS. 1 and 2A to 2D, during the process of recessing the upper portion of the second outer gate electrode OGEb, the second outer gate electrode OGEb would have been over-etched owing to the void VD in the center portion thereof. The over-etched top surface of the second outer gate electrode OGEb would have had a concave profile, thereby causing the lowermost level of the top surface of the second outer gate electrode OGEb to be at the second level LV2 lower than the first level LV1.

The gate capping pattern GP and the second interlayer insulating layer 120 could have been formed, followed by a contact hole for the gate contact. Here, since the second outer gate electrode OGEb would have had a lowered top surface, the contact hole would have also been over-etched to expose the third semiconductor pattern SP3. In this case, a short circuit could have been potentially formed between the gate contact GC (in the contact hole) and the third semiconductor pattern SP3 of the second channel pattern CH2, thereby deteriorating electric characteristics of the semiconductor device.

In contrast, according to an embodiment, as described with reference to FIGS. 10A to 10D, since the chamfering process is performed to selectively chamfer only the first preliminary metal pattern PML1 in the outer regions ORG of the first region PR when only the first region PR is exposed, the first preliminary metal pattern PML1 on the second region NR may be left. Thus, as described with reference to FIGS. 11A to 11D, the preliminary high-k dielectric layer PHK and a portion of the sacrificial insulating layer SIL may not be removed in the process of removing the first preliminary metal pattern PML1 from the second region NR. That is, the preliminary high-k dielectric layer PHK and the sacrificial insulating layer SIL in the second region NR may be protected by the first preliminary metal pattern PML1, and thus, it may be possible to prevent the recess region RSR from being formed and to prevent the upper portion of the preliminary high-k dielectric layer PHK from being inclined, as described with reference to FIG. 14B. Accordingly, since the void VD described with reference to FIG. 15 is not formed in the second outer gate electrode OGEb, it may be possible to prevent the second outer gate electrode OGEb from being over-etched. As a result, as described with reference to FIGS. 16A and 16B, it may be possible to prevent a short circuit from being formed between the gate contact GC and the second channel pattern CH2 and thereby to improve the electric characteristics of the semiconductor device.

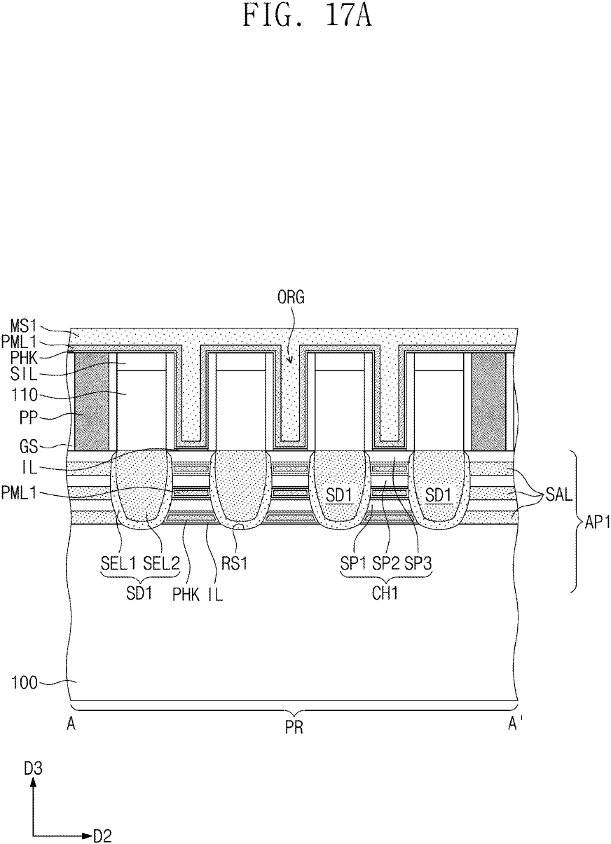

FIGS. 17A to 19B are cross-sectional views of stages in a method of fabricating a semiconductor device according to a comparative example. FIGS. 17A, 18A, and 19A are cross-sectional views corresponding to line A-A′ of FIG. 1. FIGS. 17B, 18B, and 19B are cross-sectional views corresponding to line B-B′ of FIG. 1. In the following description of the comparative example, an element previously described with reference to FIGS. 1, 2A to 2D, and 4A to 12D may be identified by the same reference number without repeating an overlapping description thereof, for concise description.

Referring to FIGS. 17A and 17B, after the process described with reference to FIGS. 9A to 9D, if the first mask MS1 were to be formed on the first region PR (i.e., to cover the first region PR and to expose the second region NR), a portion of the first preliminary metal pattern PML1 would have been removed using the first mask MS1 as an etch mask. As a result, the first preliminary metal pattern PML1 would have been left on only the first region PR.

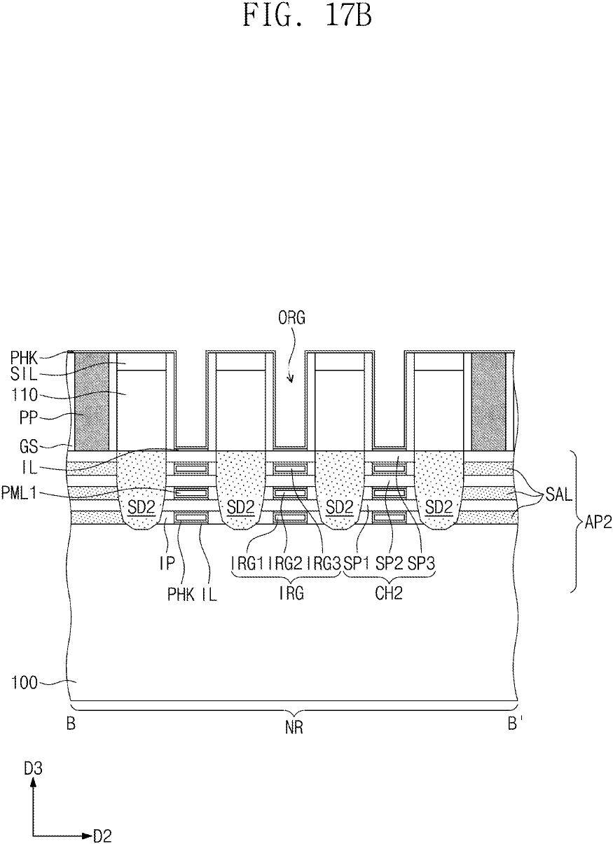

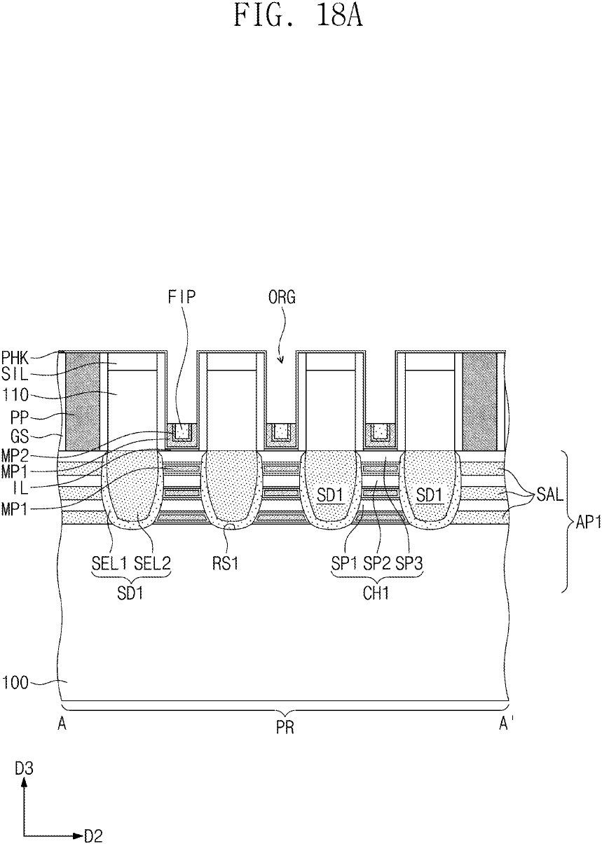

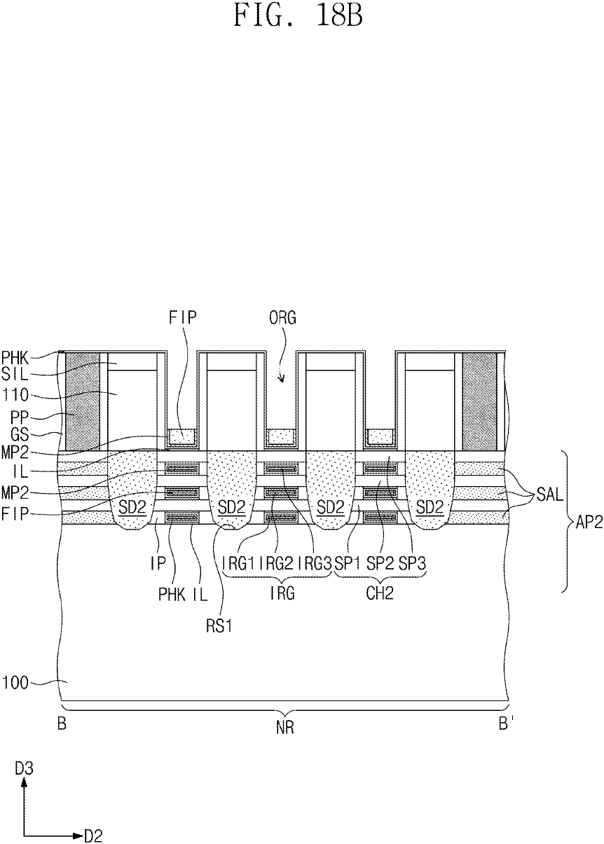

Referring to FIGS. 18A and 18B, a second preliminary metal pattern may be conformally formed. The second preliminary metal pattern may be extended along the inner side surface of the outer regions ORG of the first region PR and the top surface of the sacrificial insulating layer SIL. The second preliminary metal pattern may be extended along the inner side surfaces of the outer regions ORG of the second region NR and the top surface of the sacrificial insulating layer SIL. The second preliminary metal pattern may be extended along the inner side surfaces of the first to third inner regions IRG1, IRG2, and IRG3 of the second region NR.

The gapfill pattern FIP may be formed on the first and second regions PR and NR. The gapfill pattern FIP may fill a portion of each of the outer regions ORG of the first and second regions PR and NR. In addition, the gapfill pattern FIP may fill a remaining portion of each of the first to third inner regions IRG1, IRG2, and IRG3 of the second region NR. The top surface of the gapfill pattern FIP may be lower than the top surface of the first interlayer insulating layer 110. The gapfill pattern FIP may be formed of or include at least one of spin-on-hard mask (SOH) materials.

Both the first preliminary metal pattern PML1 and the second preliminary metal pattern would have been chamfered using the gapfill pattern FIP as an etch mask. As a result of the chamfering process, the first preliminary metal pattern PML1 and the second preliminary metal pattern, which are provided in the outer regions ORG of the first and second regions PR and NR, would have been recessed to have a lowered top surface. As a result, both the first metal pattern MP1 and the second metal pattern MP2 would have been formed to have recessed top surfaces at a level lower than the top surface of the first interlayer insulating layer 110, followed by removal of the gapfill pattern FIP.

Referring to FIGS. 19A and 19B, a process may be performed in substantially the same manner as the process described with reference to FIGS. 1, 2A to 2D, and 12A to 12D. The second metal pattern MP2 would have been extended along the inner side surface of the first metal pattern MP1 without covering the recessed topmost surface of the first metal pattern MP1 due to the previously performed chamfering (i.e., the topmost surface of the second metal pattern MP2 would have been coplanar with the topmost surface of the first metal pattern MP1 but not with the topmost surface of the high-k dielectric layer HK, the topmost surface of the third metal pattern MP3, and the topmost surface of the filling metal pattern FMP).

In the present comparative example, the chamfering process would have been performed after removing the first preliminary metal pattern PML1 on the second region NR, so the gapfill pattern FIP would have filled remaining portions of the first to third inner regions IRG1, IRG2, and IRG3 of the second region NR. In a process of removing the gapfill pattern FIP, the gapfill pattern FIP in the first to third inner regions IRG1, IRG2, and IRG3 would not have been fully removed (i.e., would have been partially left). Accordingly, the first to third inner regions IRG1, IRG2, and IRG3 of the second region NR would not have been fully filled with the third metal pattern MP3 (e.g., due to remaining portions of the gapfill pattern FIP therein), thereby deteriorating electric characteristics of the semiconductor device.

In contrast, according to an embodiment, since the first preliminary metal pattern PML1 is removed from the second region NR, after the chamfering process, the gapfill pattern FIP may not be formed in the first to third inner regions IRG1, IRG2, and IRG3 on the second region NR. That is, it may be possible to prevent the partial remains of the gapfill pattern FIP in the second region NR (and only partial third metal pattern MP3). As a result, it may be possible to realize a semiconductor device with improved electric characteristics.

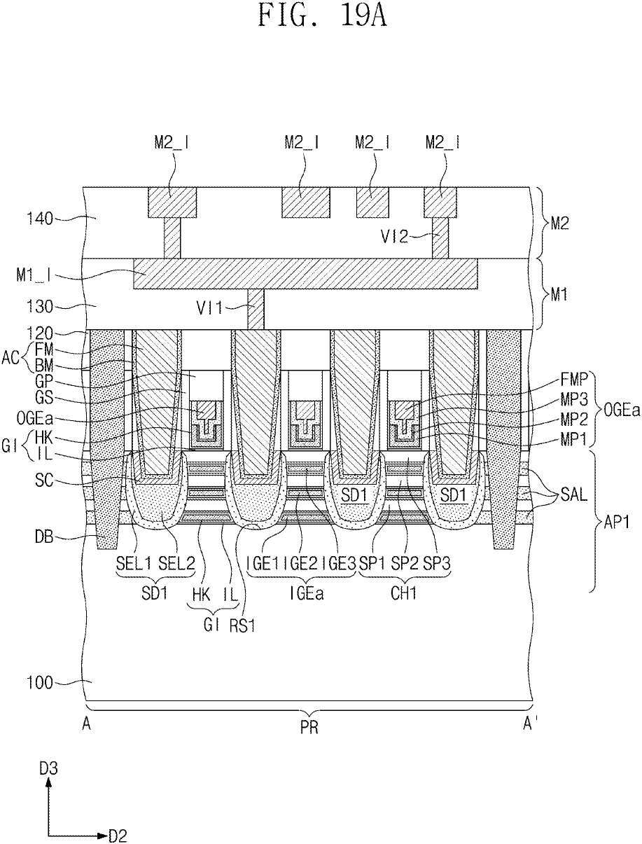

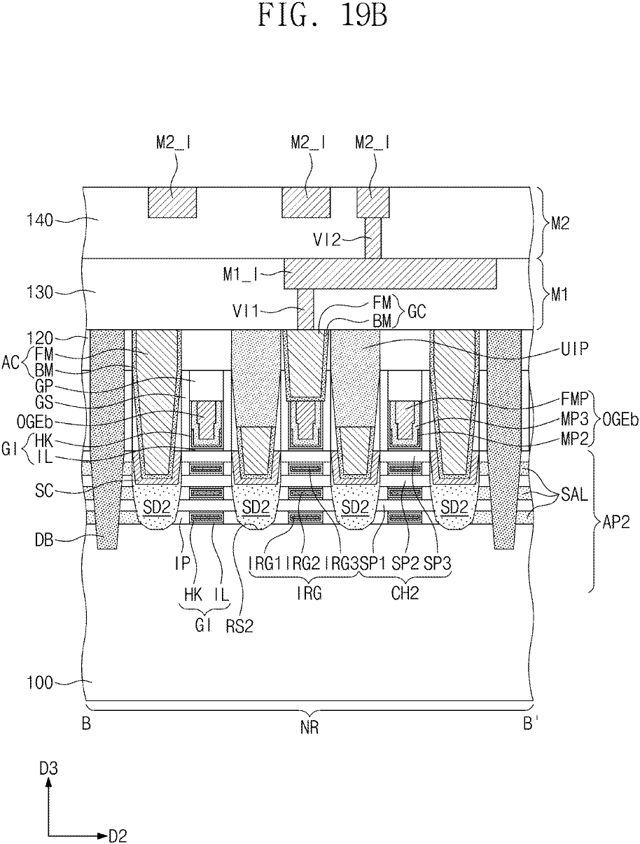

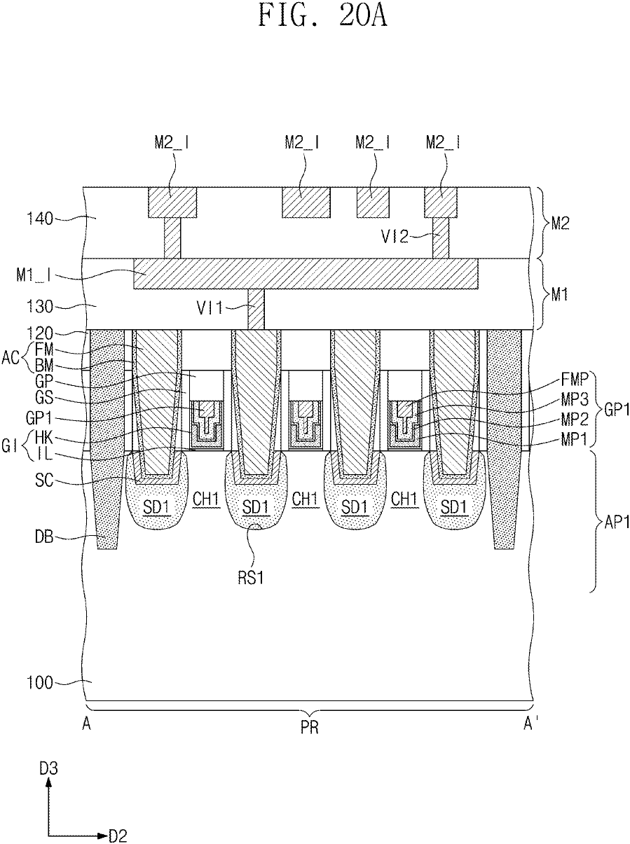

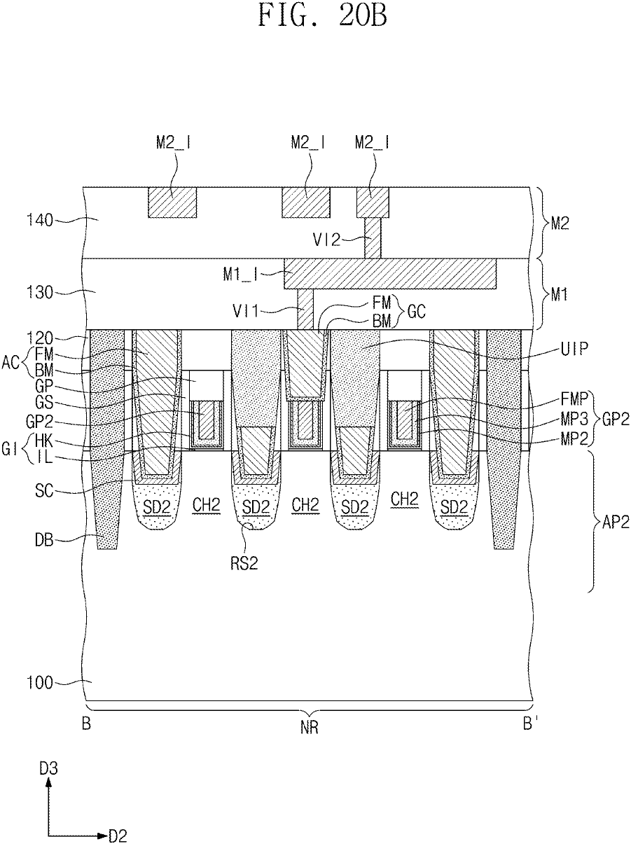

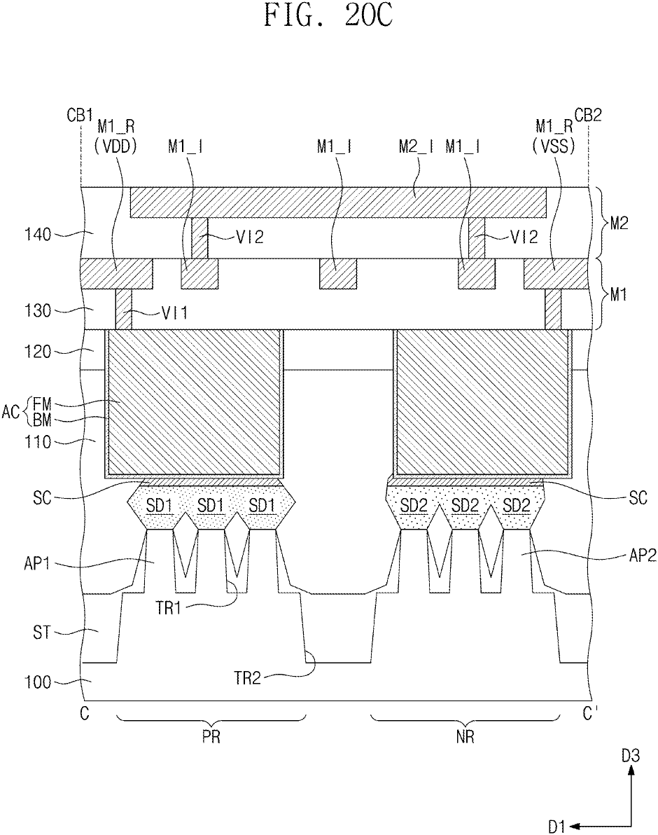

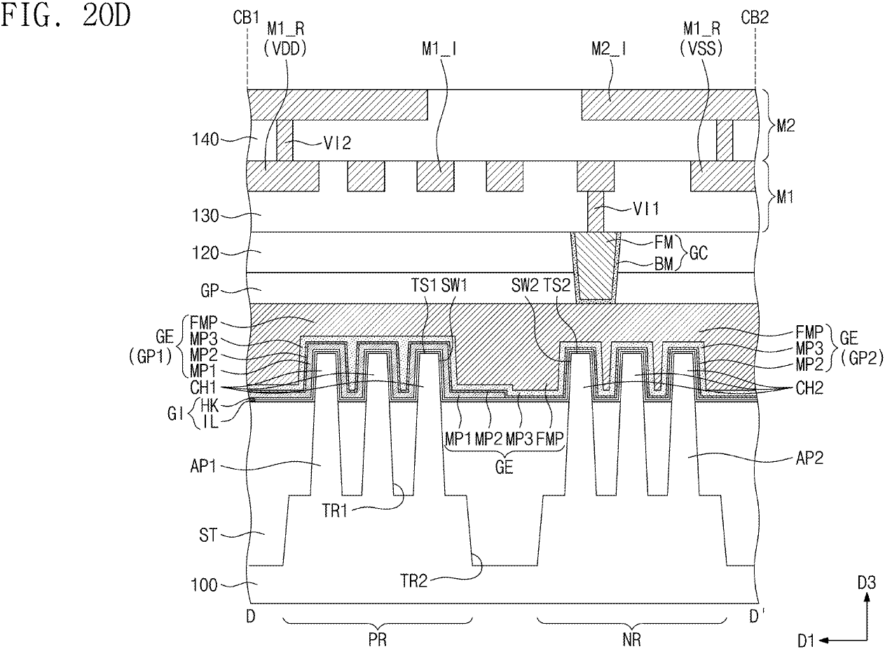

FIGS. 20A to 20D are cross-sectional views, which are respectively taken along lines A-A′, B-B′, C-C′, and D-D′ of FIG. 1 to illustrate a semiconductor device according to an embodiment. For concise description, an element previously described with reference to FIGS. 1 and 2A to 2D may be identified by the same reference number without repeating an overlapping description thereof.

Referring to FIGS. 1 and 20A to 20D, the first and second regions PR and NR may be defined by the second trench TR2, which is formed in an upper portion of the substrate 100. The first trench TR1 may be defined between adjacent ones of the first active patterns AP1 and between adjacent ones of the second active patterns AP2. The first trench TR1 may be shallower than the second trench TR2.

The device isolation layer ST may be provided to fill the first and second trenches TR1 and TR2. An upper portion of each of the first and second active patterns AP1 and AP2 may be a protruding pattern, which is vertically extended above the device isolation layer ST. The upper portion of each of the first and second active patterns AP1 and AP2 may have a fin shape. The device isolation layer ST may not cover the upper portion of each of the first and second active patterns AP1 and AP2. The device isolation layer ST may cover a lower side surface of each of the first and second active patterns AP1 and AP2.

The first source/drain patterns SD1 may be provided in the upper portions of the first active patterns AP1. The first source/drain patterns SD1 may be impurity regions of a first conductivity type (e.g., p-type). The first channel pattern CH1 may be interposed between each pair of the first source/drain patterns SD1. The second source/drain patterns SD2 may be provided in the upper portions of the second active patterns AP2. The second source/drain patterns SD2 may be impurity regions of a second conductivity type (e.g., n-type). The second channel pattern CH2 may be interposed between each pair of the second source/drain patterns SD2.

The first and second source/drain patterns SD1 and SD2 may be epitaxial patterns, which are formed by a selective epitaxial growth process. For example, the first and second source/drain patterns SD1 and SD2 may have top surfaces that are coplanar with top surfaces of the first and second channel patterns CH1 and CH2. In another example, the top surfaces of the first and second source/drain patterns SD1 and SD2 may be higher than the top surfaces of the first and second channel patterns CH1 and CH2.

The gate electrodes GE may be provided to cross the first and second active patterns AP1 and AP2 and to extend in the first direction D1. The gate electrodes GE may be vertically overlapped with the first and second channel patterns CH1 and CH2. Each of the gate electrodes GE may be provided to face a top surface and opposite side surfaces of each of the first and second channel patterns CH1 and CH2.

The gate insulating layer GI may be interposed between the gate electrode GE and the first and second channel patterns CH1 and CH2. The gate insulating layer GI may include the interface layer IL and the high-k dielectric layer HK on the interface layer IL.

The gate electrode GE may include the first gate portion GP1 on the first region PR and the second gate portion GP2 on the second region NR. The gate electrode GE may include the first metal pattern MP1, the second metal pattern MP2, the third metal pattern MP3, and the filling metal pattern FMP.

The first metal pattern MP1, the second metal pattern MP2, the third metal pattern MP3, and the filling metal pattern FMP may have substantially the same features as those in the previous embodiment described with reference to FIGS. 1 and 2A to 2D.

Referring back to FIG. 20D, the gate electrode GE may be provided on a first top surface TS1 and at least one first side surface SW1 of the first channel pattern CH1. The gate electrode GE may be provided on a second top surface TS2 of the second channel pattern CH2 and at least one second side surface SW2 of the second channel pattern CH2. In other words, the transistor according to the present embodiment may be a three-dimensional field-effect transistor (e.g., FinFET), in which the gate electrode GE is provided to surround the channel regions CH1 and CH2 three-dimensionally.

In detail, the gate insulating layer GI may conformally cover the first top surface TS1 and the at least one first side surface SW1 of the first channel pattern CH1 and the second top surface TS2 and the at least one second side surface SW2 of the second channel pattern CH2. The first metal pattern MP1, the second metal pattern MP2, and the third metal pattern MP3 may be extended along the first top surface TS1 and the at least one first side surface SW1 of the first channel pattern CH1 and the second top surface TS2 and the at least one second side surface SW2 of the second channel pattern CH2.

The gate contact GC, the active contact AC, the first metal layer M1, and the second metal layer M2 may have substantially the same features as those in the previous embodiment described with reference to FIGS. 1 and 2A to 2D.

By way of summation and review, an embodiment provides a semiconductor device with improved electric characteristics. That is, according to an embodiment, when a chamfering process is performed, only a first region may be exposed, and thus, only a first preliminary metal pattern in outer regions of the first region may be chamfered, and a first preliminary metal pattern in a second region may be left. Thus, in a process of removing the first preliminary metal pattern from the second region, a preliminary high-k dielectric layer and a sacrificial insulating layer may be partially left. In other words, the preliminary high-k dielectric layer and the sacrificial insulating layer in the second region may be protected by the first preliminary metal pattern, and thus, it may be possible to prevent an upper portion of the preliminary high-k dielectric layer from being inclined. Accordingly, a void may not be formed in a second outer gate electrode, and in this case, the second outer gate electrode may be prevented from being over-etched. As a result, it may be possible to prevent a short circuit from being formed between a gate contact and a second channel pattern and thereby to improve electric characteristics of a semiconductor device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a first active pattern and a second active pattern respectively on a first region and a second region of a substrate;
a first channel pattern on the first active pattern, the first channel pattern including first semiconductor patterns stacked to be spaced apart from each other;
a second channel pattern on the second active pattern, the second channel pattern including second semiconductor patterns stacked to be spaced apart from each other; and
a gate electrode on the first channel pattern and the second channel pattern, the gate electrode extending in a first direction,
wherein the gate electrode includes a first outer gate electrode and a second outer gate electrode on a top surface of an uppermost one of the first semiconductor patterns and a top surface of an uppermost one of the second semiconductor patterns, respectively, each of the first outer gate electrode and the second outer gate electrode including a first metal pattern, a second metal pattern on the first metal pattern, and a filling metal pattern on the second metal pattern,
wherein the first outer gate electrode further includes a third metal pattern between the first metal pattern and the first semiconductor patterns, the third metal pattern including a p-type work function metal,
wherein the second metal pattern includes an n-type work function metal, a thickness of the first metal pattern being smaller than a thickness of the second metal pattern, and
wherein a topmost surface of the first metal pattern of the second outer gate electrode is coplanar with a topmost surface of the second metal pattern of the second outer gate electrode.

2. The semiconductor device as claimed in claim 1, further comprising a gate insulating layer between the gate electrode and the first semiconductor patterns and the second semiconductor patterns,
wherein the gate insulating layer includes an interface layer and a high-k dielectric layer, the gate insulating layer enclosing the first semiconductor patterns and the second semiconductor patterns, and
wherein a topmost surface of the high-k dielectric layer is coplanar with the topmost surface of the first metal pattern.

3. The semiconductor device as claimed in claim 2, wherein the second metal pattern is spaced apart from an inner side surface of the high-k dielectric layer by the first metal pattern.

4. The semiconductor device as claimed in claim 1, wherein a lowermost level of a top surface of the first outer gate electrode is at a substantially same level as a lowermost level of a top surface of the second outer gate electrode.

5. The semiconductor device as claimed in claim 1, wherein the second outer gate electrode has a flat top surface.

6. The semiconductor device as claimed in claim 1, wherein the first metal pattern includes titanium nitride, and a thickness of the first metal pattern is smaller than a thickness of the third metal pattern.

7. The semiconductor device as claimed in claim 6, wherein:
the second metal pattern includes at least one of aluminum-doped titanium carbide, aluminum-doped tantalum carbide, aluminum-doped vanadium carbide, silicon-doped titanium carbide, and silicon-doped tantalum carbide, and
the third metal pattern includes at least one of titanium nitride, tantalum nitride, titanium oxynitride, titanium silicon nitride, titanium aluminum nitride, tungsten carbon nitride, and molybdenum nitride.

8. The semiconductor device as claimed in claim 1, wherein the third metal pattern has a recessed topmost surface, the recessed topmost surface being at a level lower than a topmost surface of the first outer gate electrode, and the first metal pattern covering the recessed topmost surface.

9. The semiconductor device as claimed in claim 1, wherein a thickness of each of the first metal pattern and the second metal pattern of the first outer gate electrode is substantially equal to a thickness of each of the first metal pattern and the second metal pattern of the second outer gate electrode.

10. The semiconductor device as claimed in claim 1, wherein:
the gate electrode further includes first inner gate electrodes in spaces between the first semiconductor patterns, and second inner gate electrodes in spaces between the second semiconductor patterns,
each of the first inner gate electrodes includes the third metal pattern, and
each of the second inner gate electrodes includes the first metal pattern and the second metal pattern.

11. A semiconductor device, comprising:
a substrate including a first region and a second region adjacent to each other in a first direction;
a first active pattern on the first region and a second active pattern on the second region;
a first channel pattern on the first active pattern and a second channel pattern on the second active pattern, the first channel pattern including first semiconductor patterns, which are stacked to be spaced apart from each other, and the second channel pattern including second semiconductor patterns, which are stacked to be spaced apart from each other;
a gate electrode crossing the first channel pattern and the second channel pattern, the gate electrode extending in the first direction, and the gate electrode including a first gate portion on the first region and a second gate portion on the second region; and
a gate insulating layer between the gate electrode and each of the first channel pattern and the second channel pattern,
wherein each of the first gate portion and the second gate portion includes a first metal pattern, a second metal pattern on the first metal pattern, and a filling metal pattern on the second metal pattern,
wherein the first gate portion further includes a third metal pattern between the first metal pattern and the first channel pattern, the third metal pattern including a p-type work function metal,
wherein the second metal pattern includes an n-type work function metal, the second metal pattern being spaced apart from an inner side surface of the gate insulating layer by the first metal pattern,
wherein a thickness of the first metal pattern is smaller than a thickness of each of the second metal pattern and the third metal patterns, and
wherein a topmost surface of the first metal pattern is flat.

12. The semiconductor device as claimed in claim 11, wherein the third metal pattern is between the first semiconductor patterns, and the first metal pattern and the second metal pattern are between the second semiconductor patterns.

13. The semiconductor device as claimed in claim 11, wherein the topmost surface of the first metal pattern is at a level higher than a topmost surface of the third metal pattern.

14. The semiconductor device as claimed in claim 11, wherein the first region is a PMOSFET region, and the second region is an NMOSFET region.

15. The semiconductor device as claimed in claim 11, wherein the topmost surface of the first metal pattern is coplanar with a topmost surface of the second metal pattern.

16. A semiconductor device, comprising:
a first active pattern and a second active pattern on a first region and a second region of a substrate, respectively, the first region and the second regions being PMOSFET and NMOSFET regions, respectively;
a device isolation layer filling a trench between the first active pattern and the second active pattern;
a first channel pattern on the first active pattern and a second channel pattern on the second active pattern, the first channel pattern including first semiconductor patterns, which are stacked to be spaced apart from each other, and the second channel pattern including second semiconductor patterns, which are stacked to be spaced apart from each other;
a gate electrode crossing the first channel pattern and the second channel pattern, the gate electrode extending in a first direction and including:
first inner gate electrodes between the first semiconductor patterns,
second inner gate electrodes between the second semiconductor patterns,
a first outer gate electrode on a top surface of an uppermost one of the first semiconductor patterns, and
a second outer gate electrode on a top surface of an uppermost one of the second semiconductor patterns;
a gate insulating layer between the gate electrode and each of the first channel pattern and the second channel pattern, the gate insulating layer including an interface layer enclosing the first and second semiconductor patterns and a high-k dielectric layer on the interface layer;
a gate capping pattern on a top surface of the gate electrode;
a first interlayer insulating layer on the gate capping pattern;
a gate contact penetrating the first interlayer insulating layer and coupled to the gate electrode;
a second interlayer insulating layer on the first interlayer insulating layer;
a first metal layer in the second interlayer insulating layer;
a third interlayer insulating layer on the second interlayer insulating layer; and
a second metal layer in the third interlayer insulating layer,
wherein each of the first outer gate electrode and the second outer gate electrode includes a first metal pattern, a second metal pattern on the first metal pattern, and a filling metal pattern on the second metal pattern,
wherein the first outer gate electrode further includes a third metal pattern between the first metal pattern and the first semiconductor patterns, the third metal pattern including a p-type work function metal,
wherein the second metal pattern includes an n-type work function metal,
wherein a thickness of the first metal pattern is smaller than a thickness of each of the second metal pattern and the third metal pattern, and
wherein a topmost surface of the first metal pattern of the second outer gate electrode is coplanar with a topmost surface of the second metal pattern of the second outer gate electrode.

17. The semiconductor device as claimed in claim 16, wherein the first metal pattern includes titanium nitride, the second metal pattern includes aluminum-doped titanium carbide, and the third metal pattern includes titanium aluminum nitride.

18. The semiconductor device as claimed in claim 16, wherein the second metal pattern is spaced apart from an inner side surface of the high-k dielectric layer by the first metal pattern.

19. The semiconductor device as claimed in claim 16, wherein the third metal pattern has a recessed topmost surface, the recessed topmost surface being at a level lower than a topmost surface of the first outer gate electrode, and the first metal pattern covering the recessed topmost surface.

20. The semiconductor device as claimed in claim 16, wherein a topmost surface of the high-k dielectric layer is coplanar with the topmost surface of the first metal pattern and the topmost surface of the second metal pattern.
